(19) United States
(12) Patent Application Publication
(10) Pub. No.: US 2022/0319932 A1
(43) Pub. Date: Oct. 6, 2022

(54) METAL GATE WITH PRETREATMENT LAYER

(71) Applicant: Taiwan Semiconductor Manufacturing Company, Ltd., Hsinchu (TW)

(72) Inventors: Peng-Soon Lim, Johor (MY); Huang-Lin Chao, Hillsboro, OR (US)

(21) Appl. No.: 17/568,654

(22) Filed: Jan. 4, 2022

Related U.S. Application Data
(60) Provisional application No. 63/169,015, filed on Mar. 31, 2021.

(51) Int. Cl. H01L 21/8234; H01L 27/088; H01L 29/78; H01L 29/423; H01L 29/06

(52) U.S. Cl. CPC H01L 21/823456; H01L 27/088; H01L 29/7851; H01L 29/42392; H01L 29/0665; H01L 29/42372

(57) ABSTRACT

A method of forming a transistor is disclosed. The method includes forming a high-k dielectric constant layer on a semiconductor substrate, forming a pretreatment layer (PL) on the high-k dielectric constant layer, determining a thickness for a conductive work function layer (WFL) based on a target effective work function of the transistor, and forming the conductive work function layer (WFL) on the first pretreatment layer, where the conductive work function layer has a WFL thickness substantially equal to the determined thickness. Forming the transistor also includes forming a coating layer on the first conductive work function layer. The gate stack has a tuned effective work function according to the determined thickness.

### TECHNICAL FIELD

The subject matter described herein relates to metal gates, and more particularly to metal gates having a pretreatment layer.

### BACKGROUND

Semiconductor manufacturing processes include numerous fabrication steps or processes, each of which contributes to the formation of one or more semiconductor layers. Each layer may be formed, for example, by doping sections of a crystalline semiconductor substrate. In addition, one or more layers may be formed by adding, for example, conductive, resistive, and/or insulative layers on the crystalline semiconductor substrate.

### DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a process of manufacturing a semiconductor device in accordance with some embodiments.

FIG. 2 is a schematic perspective view of a semiconductor substrate at one stage of manufacturing a semiconductor device in accordance with some embodiments.

FIGS. 3-20 are schematic cross-section views of a semiconductor substrate at various stages of manufacturing a high-k metal gate structure in accordance with some embodiments.

FIG. 21 is a schematic perspective view of a semiconductor substrate at one stage of manufacturing a semiconductor device in accordance with some embodiments.

FIGS. 21-29 are schematic cross-section views of a semiconductor substrate at various stages of manufacturing a high-k metal gate structure in accordance with some embodiments.

FIG. 30 is a graph illustrating a relationship between effective work function and a thickness for high-k gate structures having various levels of pretreatment.

FIG. 31 is a graph illustrating a relationship between capacitance and gate voltage for high-k gate transistors with and without pretreatment.

When practical, similar reference numbers denote similar structures, features, or elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the example processes, structures, and devices are described. A person having ordinary skill in the art will readily understand other modifications that may be made that are contemplated within the scope of other embodiments. Although process embodiments may be described in a particular order, various other process embodiments may be performed in any logical order and may include fewer or more operations than what is described herein.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

Scaling down the thickness of various layers increases performance and integration density of semiconductor devices. High-k metal gate structures, including a high-k dielectric constant layer and a conductive work function layer, are used to increase circuit performance. A coating layer comprising, for example, Silicon (Si) on the conductive work function layer allows for the conductive work function layer to be thinner, resulting in lower effective work function, and for better ability to scale to future technologies having smaller fabrication dimensions. However, a thinner conductive work function layer can result in poor control of effective work function and corresponding threshold voltage, and can result in poor interface trap density (Dit).

As used herein, the term “high-k” may refer to a dielectric constant k that is higher than the dielectric constant of silicon dioxide. High-k materials typically have a lower equivalent oxide thickness than SiO2 so they could retain an appropriate gate oxide thickness to prevent leakage current while also increasing the switching speed. High-k materials allow reducing leakage while keeping a very low electrical equivalent oxide thickness. Hence, efforts to realize interconnects using low-k dielectric and low leakage gate oxide employing high-k dielectric for shrinking sizes of semiconductor devices have been made.

High-k gate structures may include high-k dielectric materials and a conductive work function metal material. The conductive work function metal materials may include aluminum (Al) based—for example, TiAlC or TaAlC. The conductive workfunction metal material of the high-k gate structure may require thick protection layer to prevent the Al from oxidation. Thus, thicker or higher Al-dose is typically used in some high-k gate structure forming processes to push effective work function (eWF) of the high-k gate structure almost towards band edge. For example, when TiAlC is used in some of the processes for forming high-k gate structures, percentage of Al and/or thickness of the TiAlC is typically controlled to modulate eWF towards N-type band edge. In those processes, the threshold voltage (Vt) and Dit can become poor. The inventors of the present disclosure realize such a high-k gate structure can limit scaling capability of the high-k gate structure.

One motivation for the present disclosure is to address the aforementioned problem of thick protection layer for high-k gate structures leading to limited scaling.

Embodiments discussed herein have a pretreatment layer formed on the high-k dielectric constant layer, and a thin conductive work function layer formed on the pretreatment layer. As a result, the embodiments have the advantages of a thinner conductive work function layer and have good control of effective work function and corresponding threshold voltage, and have good Dit.

Some embodiments are described in the context of a replacement gate process. Implementations of some aspects may be used in other example processes. For example, other example processes can include a gate-first or other transistor fabrication processes.

Some embodiments are described in the context of FinFETs. The fins of FinFETs may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Implementations of some aspects may be used in other devices. For example, other devices such as nanostructure transistors, which include Gate All Around (GAA) FETs, Horizontal Gate All Around (HGAA) FETs, Vertical Gate All Around (VGAA) FETs, nanowire channel FETs, and other devices, for example, such as those including nanosheet structures.

A person having ordinary skill in the art will readily understand that implementations of some or all aspects may be used in certain or any other transistor structures.

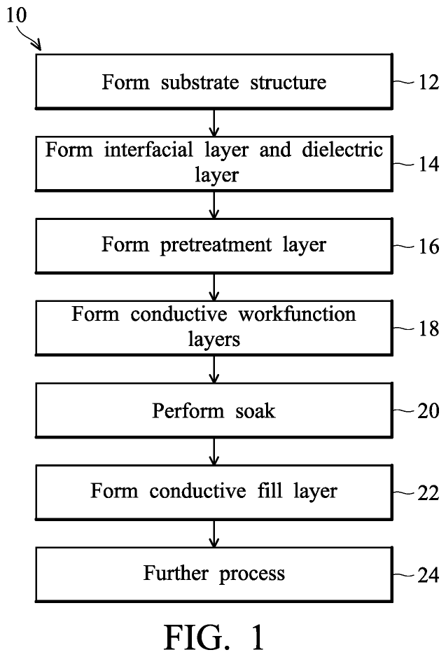

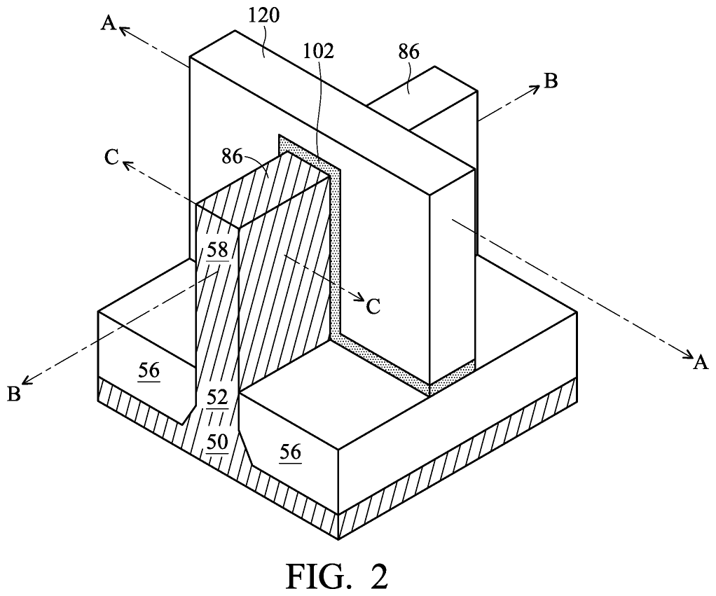

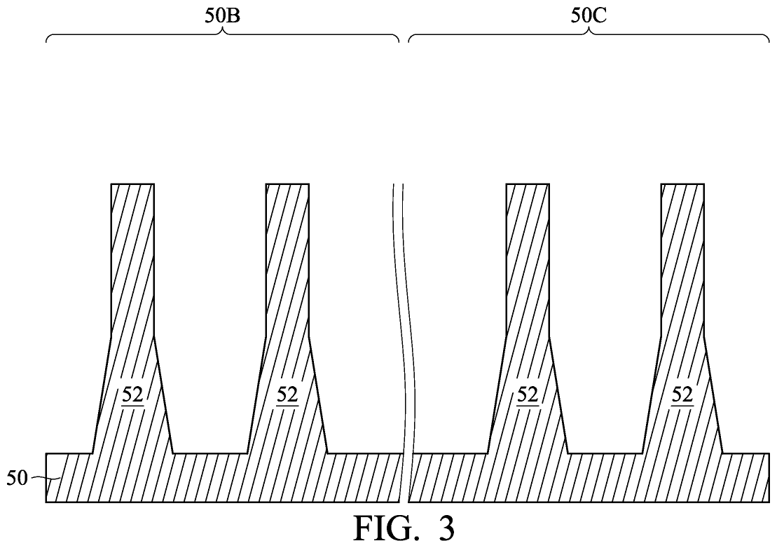

FIG. 1 depicts an exemplary flow diagram of a process 10 performed to form a gate structure, such as described with respect to FIG. 2 to FIG. 20. FIG. 2 is a schematic perspective view and FIG. 3 to FIG. 20 are schematic cross-sectional views of portions of the substrate illustrating gate stacks of transistors corresponding to various stages of the process 10 in accordance with some embodiments. The process 10 may be utilized to form any suitable structures.

FIG. 2 illustrates an example of a FinFET which can be formed using the process 10 of FIG. 1, in accordance with some embodiments. The FinFET is illustrated in a three-dimensional view, and comprises a fin 58 on a substrate 50. Isolation regions 56 are formed on the substrate 50, and the fin 58 protrudes above and from between neighboring isolation regions 56. A gate dielectric layer 102 is along sidewalls and over a top surface of the fin 58, and a gate electrode 120 is over the gate dielectric layer 102. Source/drain regions 86 are disposed in opposite sides of the fin 58 with respect to the gate dielectric layer 102 and gate electrode 120. FIG. 2 further illustrates reference cross-sections that are used in later figures. Cross-section A-A is across a channel, gate dielectric layer 102, and gate electrode 120 of the FinFET. Cross-section B-B is perpendicular to cross-section A-A and is along a longitudinal axis of the fin 58 and in a direction of, for example, a current flow between the source/drain regions 86. Cross-section C-C is parallel to cross-section A-A and extends through a source/drain region of the FinFET Subsequent figures refer to these reference cross-sections for clarity.

Some embodiments discussed herein are discussed in the context of FinFETs formed using a gate-last process. In other embodiments, a gate-first process may be used. Also, some embodiments contemplate aspects used in planar devices, such as planar FETs.

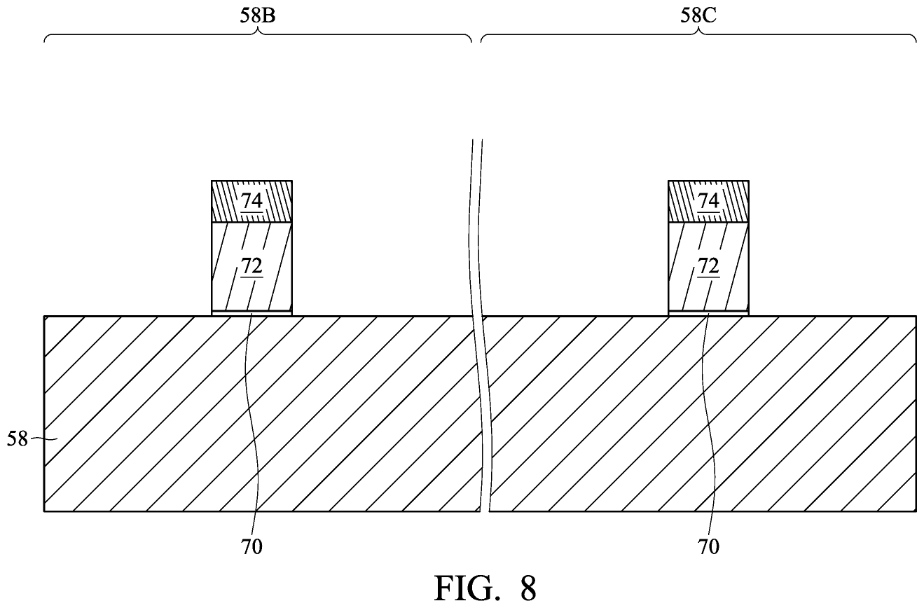

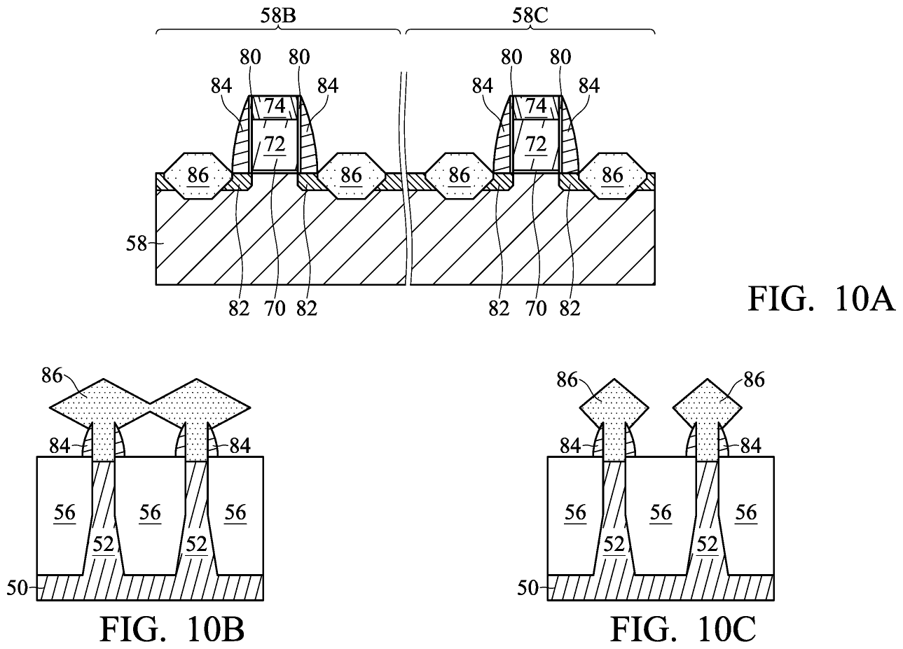

FIGS. 3-20 are cross-sectional views of intermediate stages in the manufacturing of FinFETs, in accordance with some embodiments of process 10 of FIG. 1. FIGS. 3 through 7 illustrate multiple FinFETs each shown along reference cross-section A-A illustrated in FIG. 2. FIGS. 8 through 10A, and 11-20 illustrate multiple FinFETs each shown along reference cross-section B-B illustrated in FIG. 2. FIGS. 10B and 10C illustrate multiple FinFETs each shown along reference cross-section C-C illustrated in FIG. 2.

At operation 12 of the process 10 of FIG. 1, fin structures are formed in a substrate 50, as shown in FIG. 3. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The substrate 50 has a region 50B and a region 50C. The region 50B can be for forming n-type devices, such as NMOS transistors, e.g., n-type FinFETs. The region 50C can be for forming p-type devices, such as PMOS transistors, e.g., p-type FinFETs. The region 50B may be physically separated from the region 50C (as illustrated by a divider), and any number of device features (e.g., other active devices, doped regions, isolation structures, etc.) may be disposed between the region 50B and the region 50C. In some embodiments, both the region 50B and the region 50C are used to form the same type of devices, such as both regions being for n-type devices or p-type devices.

The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), the like, or a combination thereof. The etch may be anisotropic.

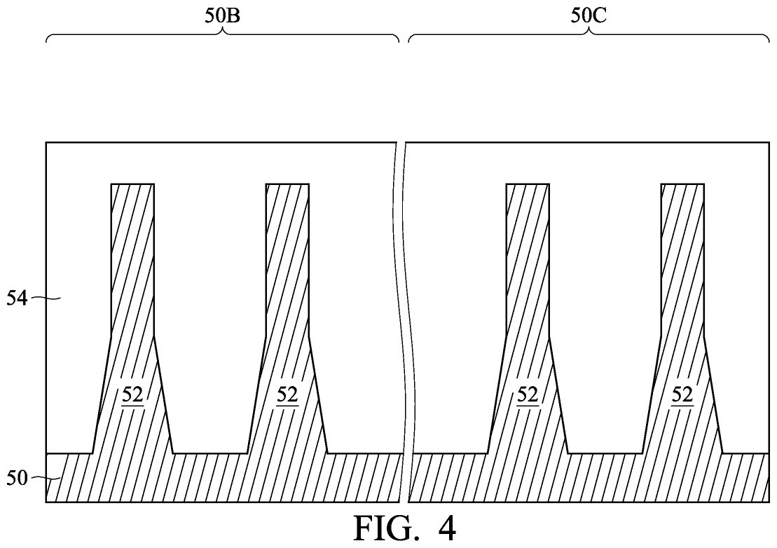

Also at operation 12 of the process 10 of FIG. 1, an insulation material 54 is formed over the substrate 50 and between neighboring fins 52, as shown in FIG. 4. The insulation material 54 may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52.

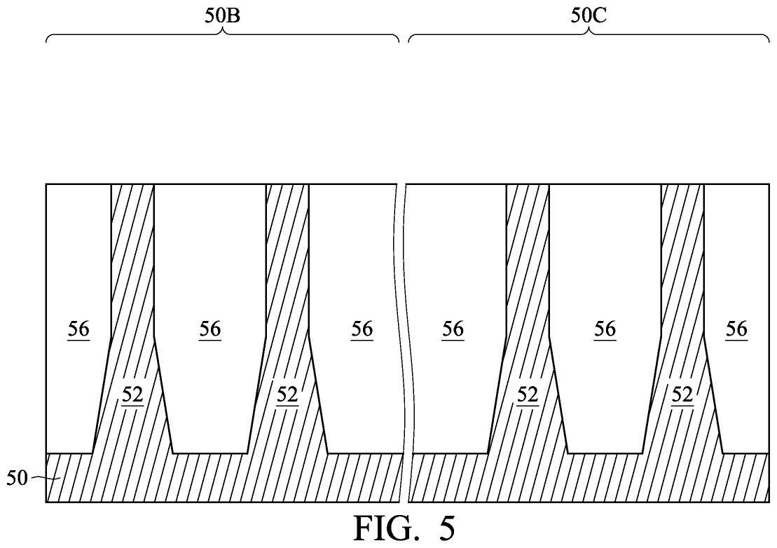

Also at operation 12 of the process 10 of FIG. 1, a planarization process is applied to the insulation material 54, as shown in FIG. 5. In some embodiments, the planarization process includes a chemical mechanical polish (CMP), an etch back process, combinations thereof, or the like. The planarization process exposes the fins 52. Top surfaces of the fins 52 and the insulation material 54 are level after the planarization process is complete.

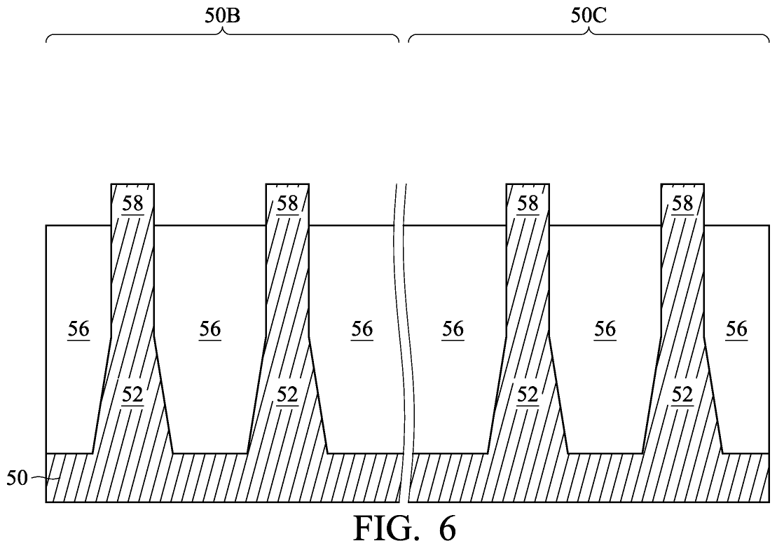

Also at operation 12 of the process 10 of FIG. 1, the insulation material 54 is recessed to form Shallow Trench Isolation (STI) regions 56, as shown in FIG. 6. The insulation material 54 is recessed such that fins 58 in the region 50B and in the region 50C protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54. For example, a chemical oxide removal etch or an Applied Materials SICONI tool or dilute hydrofluoric (dHF) acid may be used.

A person having ordinary skill in the art will readily understand that the process described with respect to FIGS. 3 through 6 is just one example of how the fins 58 may be formed. In some embodiments, a dielectric layer can be formed over a top surface of the substrate 50; trenches can be etched through the dielectric layer; homoepitaxial structures can be epitaxially grown in the trenches; and the dielectric layer can be recessed such that the homoepitaxial structures protrude from the dielectric layer to form fins. In some embodiments, heteroepitaxial structures can be used for the fins 52. For example, the fins 52 in FIG. 5 can be recessed, and a material different from the fins 52 may be epitaxially grown in their place. In an even further embodiment, a dielectric layer can be formed over a top surface of the substrate 50; trenches can be etched through the dielectric layer; heteroepitaxial structures can be epitaxially grown in the trenches using a material different from the substrate 50; and the dielectric layer can be recessed such that the heteroepitaxial structures protrude from the dielectric layer to form the fins 58. In some embodiments where homoepitaxial or heteroepitaxial structures are epitaxially grown, the grown materials may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fins 58 may be formed from silicon germanium (SixGe1−x, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

Further, appropriate doped regions (not shown, sometimes referred to as well regions) may be formed in the fins 58, the fins 52, and/or the substrate 50. In some embodiments, a P-type doped region may be formed in the region 50B, and an N-type doped region may be formed in the region 50C. In some embodiments, only P-type or only N-type doped regions are formed in both the region 50B and the region 50C.

In the embodiments with different types of doped regions, the different implant steps for the region 50B and the region 50C may be achieved using a photoresist or other masks (not shown). For example, a photoresist may be formed over the fins 58 and the STI regions 56 in the region 50B. The photoresist is patterned to expose the region 50C of the substrate 50, such as a PMOS region. The photoresist can be formed by using a spin-on technique and can be patterned using acceptable photolithography techniques. Once the photoresist is patterned, an n-type impurity implant is performed in the region 50C, and the photoresist may act as a mask to substantially prevent n-type impurities from being implanted into the region 50B, such as an NMOS region. The n-type impurities may be phosphorus, arsenic, or the like implanted in the region to a concentration of equal to or less than 10¹⁸ cm-3, such as from about 10¹⁷ cm-3 to about 10¹⁸ cm-3. After the implant, the photoresist is removed, such as by an acceptable ashing process. Following the implanting of the region 50C, a photoresist is formed over the fins 58 and the STI regions 56 in the region 50C. The photoresist is patterned to expose the region 50B of the substrate 50, such as the NMOS region. The photoresist can be formed by using a spin-on technique and can be patterned using acceptable photolithography techniques. Once the photoresist is patterned, a p-type impurity implant may be performed in the region 50B, and the photoresist may act as a mask to substantially prevent p-type impurities from being implanted into the region 50C, such as the PMOS region. The p-type impurities may be boron, BF2, or the like implanted in the region to a concentration of equal to or less than 10¹⁸ cm-3, such as from about 10¹⁷ cm-3 to about 10¹⁸ cm-3. After the implant, the photoresist may be removed, such as by an acceptable ashing process. After the implants of the region 50B and the region 50C, an anneal may be performed to activate the p-type and/or n-type impurities that were implanted. In some embodiments, the grown materials of epitaxial fins may be in situ doped during growth, which may obviate the implantations, although in situ and implantation doping may be used together.

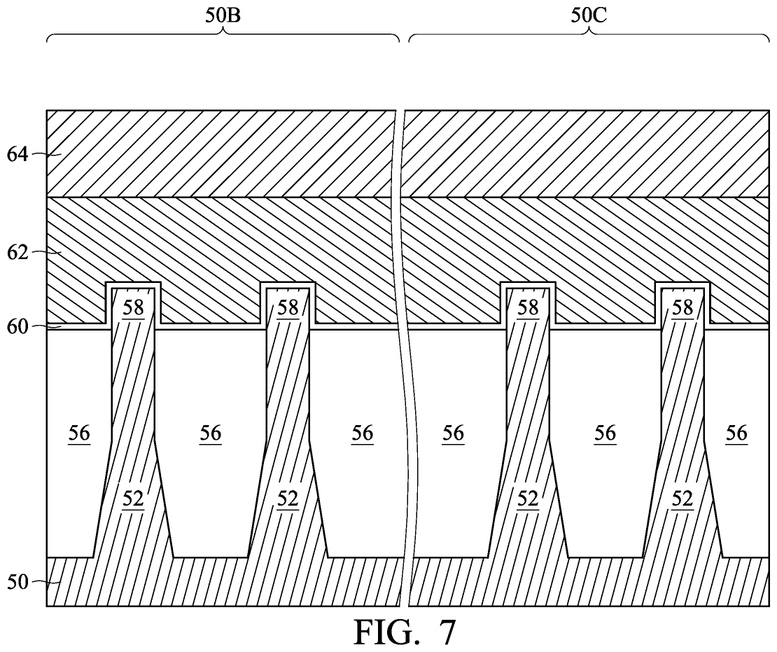

Also at operation 12 of the process 10 of FIG. 1, a dummy dielectric layer 60 is formed over the fins 58, as shown in FIG. 7. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized, such as by a CMP. The dummy gate layer 62 may be a conductive material and may be selected from a group including polycrystalline-silicon (polysilicon), poly-crystalline silicon-germanium (poly-SiGe), metallic nitrides, metallic silicides, metallic oxides, and metals. In one embodiment, amorphous silicon is deposited and recrystallized to create polysilicon. The dummy gate layer 62 may be deposited by physical vapor deposition (PVD), CVD, sputter deposition, or other techniques known and used in the art for depositing conductive materials. The dummy gate layer 62 may be made of other materials that have a high etching selectivity from the etching of isolation regions. The mask layer 64 may be deposited over the dummy gate layer 62. The mask layer 64 may include, for example, SiN, SiON, or the like. In this example, a single dummy gate layer 62 and a single mask layer 64 are formed across the region 50B and the region 50C. In some embodiments, separate dummy gate layers may be formed in the region 50B and the region 50C, and separate mask layers may be formed in the region 50B and the region 50C.

FIGS. 8-20 are cross-sectional views of intermediate stages in the manufacturing of FinFETs, in accordance with some embodiments. FIGS. 8-10A and 11-20 are shown along reference cross-section B-B illustrated in FIG. 1, except for multiple fins/FinFETs. FIGS. 10B-10C are shown along reference cross-section C-C illustrated in FIG. 1, except for multiple fins/FinFETs.

FIGS. 8-20 illustrate a region 58B and a region 58C of one or more of the fins 58. The regions 58B and 58C may be in the same fin 58 or different fins 58. Devices in the different regions 58B and 58C are formed to have different conductivity types.

Also at operation 12 of the process 10 of FIG. 1, the mask layer 64 is patterned using acceptable photolithography and etching techniques to form masks 74, as shown in FIG. 8. The pattern of the masks 74 then may be transferred to the dummy gate layer 62 and the dummy dielectric layer 60 by an acceptable etching technique to, respectively, form dummy gates 72 and dummy gate dielectric layers 70. The dummy gates 72 and dummy gate dielectric layers 70 cover respective channel regions of the fins 58. The pattern of the masks 74 may be used to physically separate each of the dummy gates 72 from adjacent dummy gates. The dummy gates 72 may also have a lengthwise direction substantially perpendicular to the lengthwise direction of respective epitaxial fins.

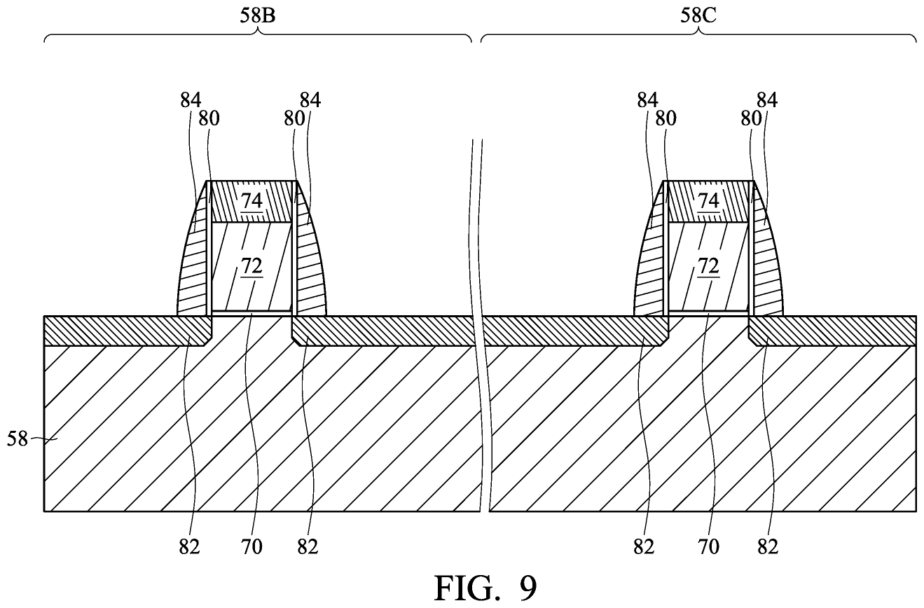

Also at operation 12 of the process 10 of FIG. 1, gate seal spacers 80 can be formed on exposed surfaces of the dummy gates 72 and/or the fins 58, as shown in FIG. 9. A thermal oxidation or a deposition followed by an anisotropic etch may form the gate seal spacers 80. In some embodiments, the gate seal spacers 80 may be formed of a nitride, such as silicon nitride, silicon oxynitride, silicon carbide, silicon carbonitride, the like, or a combination thereof. The gate seal spacers 80 seal the sidewalls of subsequently formed gate stacks, and may act as additional gate spacing layers.

Further, implants for lightly doped source/drain (LDD) regions 82 may be performed. In the embodiments with different device types, similar to the implants discussed above in FIG. 6, a mask, such as a photoresist, may be formed over the first region 50B, while exposing the second region 50C, and appropriate type (e.g., n-type or p-type) impurities may be implanted into the exposed fins 58 in the second region 50C. The mask may then be removed. Subsequently, a mask, such as a photoresist, may be formed over the second region 50C while exposing the first region 50B, and appropriate type impurities may be implanted into the exposed fins 58 in the first region 50B. The mask may then be removed. The n-type impurities may be the any of the n-type impurities previously discussed, and the p-type impurities may be the any of the p-type impurities previously discussed. The lightly doped source/drain regions may have a concentration of impurities of from about 10¹⁵ cm-3 to about 10¹⁶ cm-3. An anneal may be used to activate the implanted impurities.

Further, gate spacers 84 are formed on the gate seal spacers 80 along sidewalls of the dummy gates 72 and over the LDD regions 82. The gate spacers 84 may be formed by conformally depositing a material and subsequently anisotropically etching the material. The material of the gate spacers 84 may be silicon nitride, SiCN, a combination thereof, or the like. The etch may be selective to the material of the gate spacers 84, such that the LDD regions 82 are not etched during the formation of the gate spacers 84.

Also at operation 12 of the process 10 of FIG. 1, epitaxial source/drain regions 86 are formed in the fins 58, as shown in FIGS. 10A, 10B, and 10C. The epitaxial source/drain regions 86 are formed in the fins 58 such that each dummy gate 72 is disposed between respective neighboring pairs of the epitaxial source/drain regions 86. In some embodiments, the epitaxial source/drain regions 86 may extend through the LDD regions 82. In some embodiments, the gate seal spacers 80 and gate spacers 84 are used to separate the epitaxial source/drain regions 86 from the dummy gates 72 by an appropriate lateral distance so that the epitaxial source/drain regions 86 do not short out subsequently formed gates of the resulting FinFETs.

The epitaxial source/drain regions 86 in the region 50B, e.g., the NMOS region, may be formed by masking the region 50C, e.g., the PMOS region, and etching source/drain regions of the fins 58 in the region 50B to form recesses in the fins 58. Then, the epitaxial source/drain regions 86 in the region 50B are epitaxially grown in the recesses. The epitaxial source/drain regions 86 may include any acceptable material, such as appropriate for n-type FinFETs. For example, if the fins 58 are silicon, the epitaxial source/drain regions 86 in the region 50B may include silicon, SiC, SiCP, SiP, or the like. The epitaxial source/drain regions 86 in the region 50B may have surfaces raised from respective surfaces of the fins 58 and may have facets.

The epitaxial source/drain regions 86 in the region 50C, e.g., the PMOS region, may be formed by masking the region 50B, e.g., the NMOS region, and etching source/drain regions of the fins 58 in the region 50C to form recesses in the fins 58. Then, the epitaxial source/drain regions 86 in the region 50C are epitaxially grown in the recesses. The epitaxial source/drain regions 86 may include any acceptable material, such as appropriate for p-type FinFETs. For example, if the fins 58 are silicon, the epitaxial source/drain regions 86 in the region 50C may comprise SiGe, SiGeB, Ge, GeSn, or the like. The epitaxial source/drain regions 86 in the region 50C may also have surfaces raised from respective surfaces of the fins 58 and may have facets.

The epitaxial source/drain regions 86 are in situ doped during growth to form source/drain regions. The epitaxial source/drain regions 86 have the same doping type as the respective LDD regions 82, and may be doped with the same dopants or different dopants. The epitaxial source/drain regions 86 may have an impurity concentration of between about 10¹⁹ cm-3 and about 10²¹ cm-3. The n-type and/or p-type impurities for source/drain regions may be any of the impurities previously discussed. Because the epitaxial source/drain regions 86 are in situ doped during growth, they are not doped by implantation. However, the doping profile and concentration of the LDD regions 82 produced according to some embodiments may be similar to that which would be produced if the epitaxial source/drain regions 86 were doped by implantation. Improving the doping profile and concentration of the LDD regions 82 may improve the performance and reliability of the resulting semiconductor devices.

As a result of the epitaxy processes used to form the epitaxial source/drain regions 86 in the region 50B and the region 50C, upper surfaces of the epitaxial source/drain regions have facets which expand laterally outward beyond a sidewalls of the fins 58. In some embodiments, these facets cause adjacent epitaxial source/drain regions 86 of a same finFET to merge, as illustrated by the embodiment of FIG. 10B. In other embodiments, adjacent epitaxial source/drain regions 86 remain separated after the epitaxy process is completed, as illustrated by the embodiment of FIG. 10C.

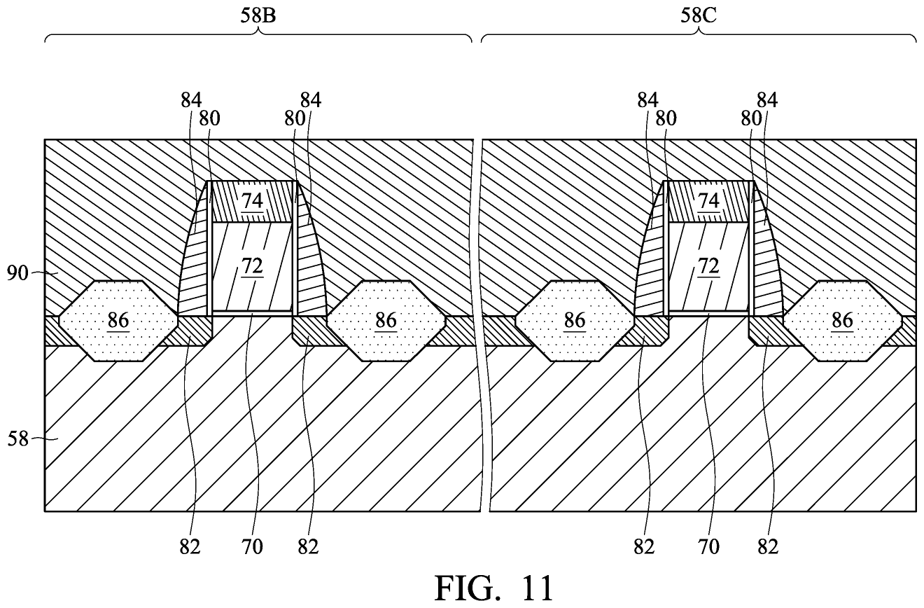

Also at operation 12 of the process 10 of FIG. 1, an ILD 90 is deposited over the fins 58, as shown in FIG. 11. The ILD 90 may be formed of a dielectric material or a semiconductor material, and may be deposited by any suitable method, such as CVD, plasma-enhanced CVD (PECVD), or FCVD. Dielectric materials may include Phospho-Silicate Glass (PSG), Boro-Silicate Glass (BSG), Boron-Doped Phospho-Silicate Glass (BPSG), undoped Silicate Glass (USG), or the like. Semiconductor materials may include amorphous silicon, silicon germanium (SixGe1−x, where x can be between approximately 0 and 1), pure Germanium, or the like. Other insulation or semiconductor materials formed by any acceptable process may be used. In some embodiments, a contact etch stop layer (CESL), not illustrated, is disposed between the ILD 90 and the epitaxial source/drain regions 86, the gate spacers 84, the gate seal spacers 80, and the masks 74.

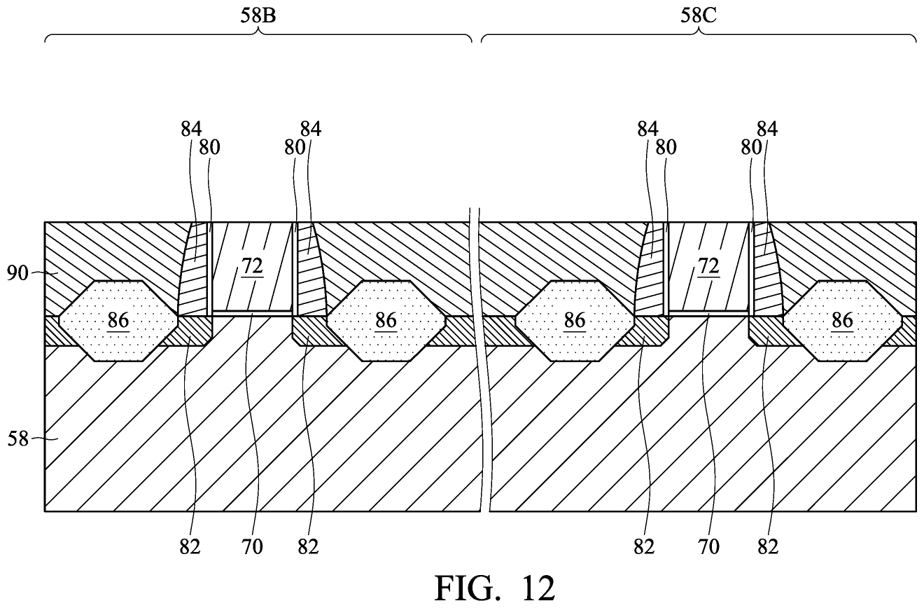

Also at operation 12 of the process 10 of FIG. 1, a planarization process, such as a CMP, may be performed to level the top surface of the ILD 90 with the top surfaces of the dummy gates 72, as shown in FIG. 12. The planarization process may also remove the masks 74 on the dummy gates 72, and portions of the gate seal spacers 80 and the gate spacers 84 along sidewalls of the masks 74. After the planarization process, top surfaces of the dummy gates 72, the gate seal spacers 80, the gate spacers 84, and the ILD 90 are level. Accordingly, the top surfaces of the dummy gates 72 are exposed through the ILD 90.

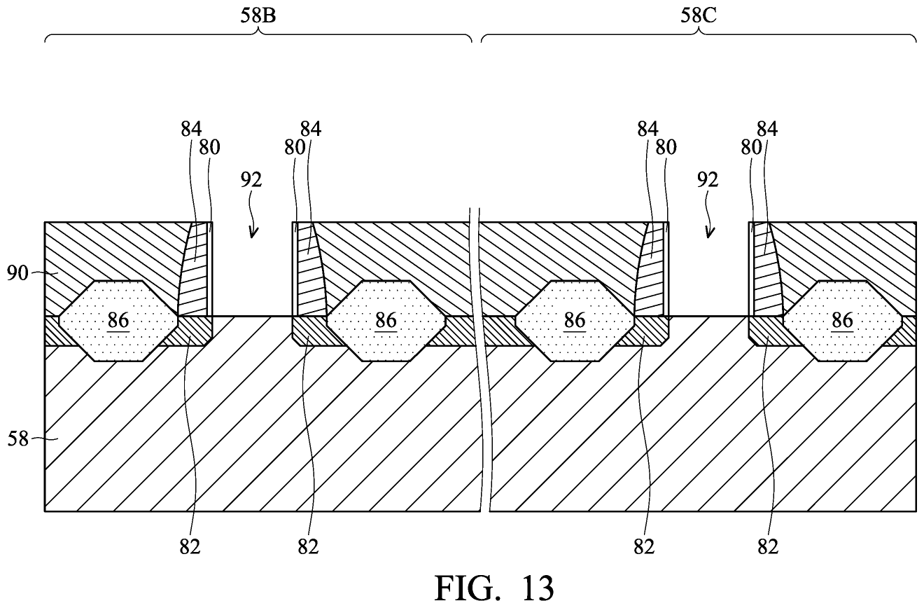

Also at operation 12 of the process 10 of FIG. 1, the dummy gates 72 and portions of the dummy gate dielectric layers 70 directly underlying the exposed dummy gates 72 are removed in an etching step(s), so that recesses 92 are formed, as shown in FIG. 13. In some embodiments, the dummy gates 72 are removed by an anisotropic dry etch process. For example, the etching process may include a dry etch process using reaction gas(es) that selectively etch the dummy gates 72 without etching the ILD 90, the gate spacers 84, or the gate seal spacers 80. Each recess 92 exposes a channel region of a respective fin 58. Each channel region is disposed between neighboring pairs of the epitaxial source/drain regions 86. During the removal, the dummy gate dielectric layers 70 may be used as an etch stop layer when the dummy gates 72 are etched. The dummy gate dielectric layers 70 may then be removed after the removal of the dummy gates 72.

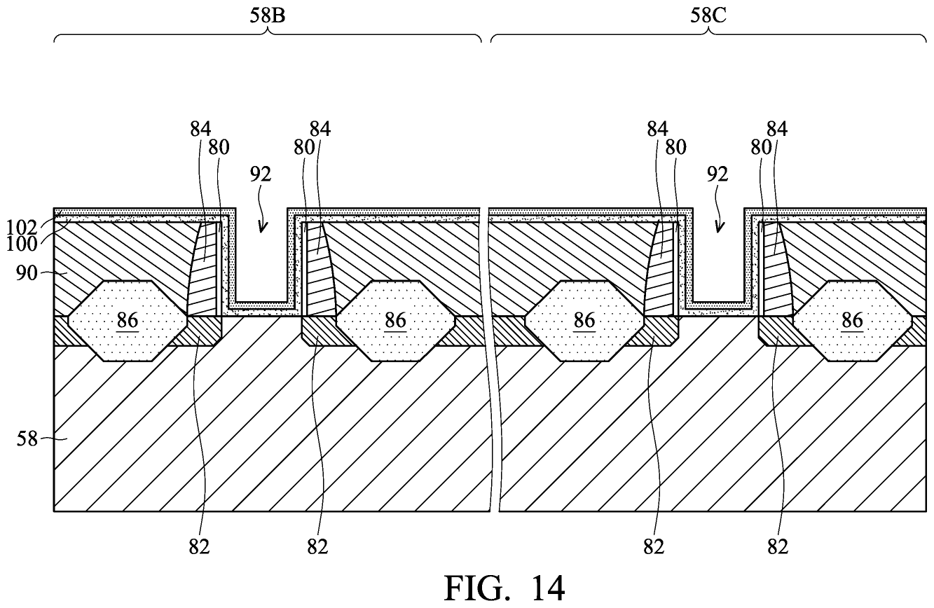

At operation 14 of the process 10 of FIG. 1, an interface layer 100 is formed in the recesses 92, as shown in FIG. 14. The interface layer 100 is conformally formed over the fin 58, and thus the interface layer 100 lines sidewalls and the bottom surface of the recesses 92. The interface layer 100 may also cover the upper surface of the ILD 90. In accordance with some embodiments, the interface layer 100 is an oxide of the material of the fin 58, and may be formed by, e.g., oxidizing the fins 58 in the recesses 92. In certain embodiments, the interfacial layer 100 may include a dielectric material such as a silicon oxide layer (SiO2), a silicon oxynitride (SiON) layer, and the like. The interface layer 100 may also be formed by a deposition process, such as a chemical vapor deposition (CVD) process, a physical vapor deposition (PVD) process, an atomic layer deposition (ALD) process, or the like. The interfacial layer 100 maybe formed to an initial thickness in a range from about 5 Å to about 10 A.

Also at operation 14 of the process 10 of FIG. 1, a gate dielectric layer 102 is formed over the interface layer 100, as shown in FIG. 14. The gate dielectric layer 102 may be deposited conformally in the recesses 92, such as on the top surfaces and the sidewalls of the fins 58 and on sidewalls of the interface layer 100 in the recesses 92. The gate dielectric layer 102 may also be formed along top surfaces of the ILD 90. In accordance with some embodiments, the gate dielectric layer 102 is a high-k dielectric material having a k value greater than about 7.0, and may include a metal oxide or a silicate of Hf, Al, Zr, La, Mg, Ba, Ti, Pb, and combinations thereof. In some embodiments, the dielectric layer 102 may comprise hafnium oxide (HfOx), AlOx, lanthanum oxide (LaOx), LaSixOy, HfLaxOy, TiOx, HfZrxOy, HfSixOy, ZrOx, ZrSixOy, TaOx, YOx, SrTixOy, BaTixOy (BTO), BaZrxOy, HfZrxOy, HfZrxOyNz, HfLaxOy, HfSixOy, HfSixOyNz, LaSixOy, AlSixOy, HfTaxOy, HfTixOy, (Ba,Sr)TixOy (BST), combinations thereof, or other suitable material. In certain embodiments, the high-k dielectric constant layer 102 comprises LaOx, LaSixOy, HfLaxOy, or combinations thereof. The formation methods of the gate dielectric layer 102 may include Molecular-Beam Deposition (MBD), ALD, CVD, PECVD, and the like. In other embodiments, the dielectric layer 102 may be directly formed on the fins 58 if the interfacial layer 100 is not present.

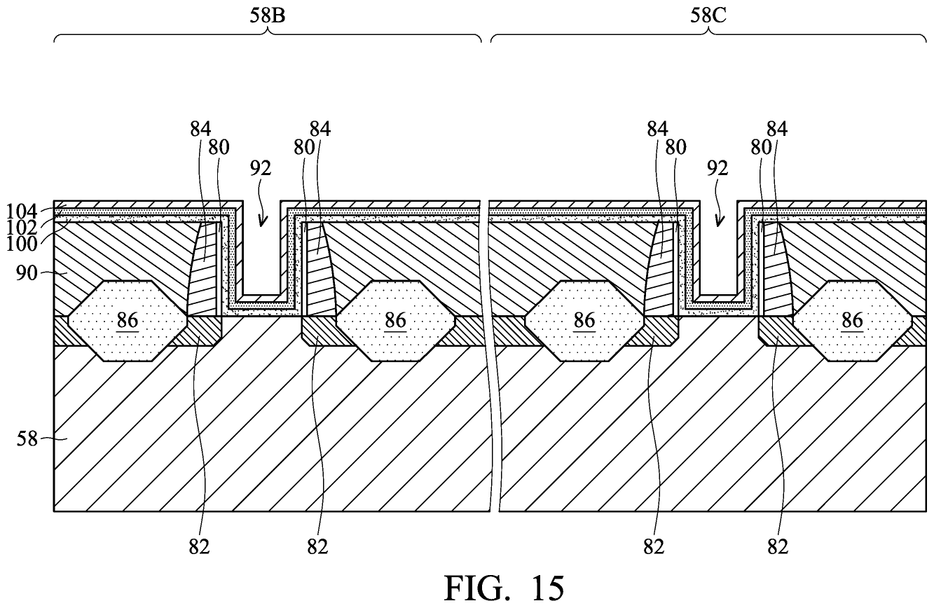

At operation 16 of the process 10 of FIG. 1, one or more pretreatment layers 104 are deposited over the dielectric layer 102, as shown in FIG. 15. One or more pretreatment layers 104 are used to pretreat the dielectric layer 102 so that, for example, an acceptable Dit can be achieved in the transistors that are formed. Examples of a pretreatment layers 104 for the transistors include Al-based alloy, Al-based metal carbide or Al-based metal nitride such as TaAl, TaAlC, TaAlN, or TiAl, TiAlC or TiAlN, AlOxCy (e.g. with C less than about 30%, about 25%, about 20%, about 15%, or about 10%), other suitable pretreatment layer materials, or combinations thereof.

The one or more pretreatment layers 104 may have a combined thickness in a range from about 2.5 angstroms to about 30 angstroms. For example, the one or more pretreatment layers 104 may have a combined thickness of less than about 2.5 A. In some embodiments, the one or more pretreatment layers 104 has a combined thickness of about 2.5 A, about 5 A, about 7.5 A, about 10 A, about 12.5 A, about 15 A, about 17.5 A, about 20 A, about 22.5 A, about 25 A, about 27.5 Å, or about 30 A. In some embodiments, the one or more pretreatment layers 104 may have a combined thickness of greater than about 30 A. In some embodiments, the one or more pretreatment layers 104 of the transistor formed in region 50B has the same or substantially the same thickness as the one or more pretreatment layers 104 of the transistor formed in region 50C. In some embodiments, the one or more pretreatment layers 104 of the transistor formed in region 50B has a different thickness as the one or more pretreatment layers 104 of the transistor formed in region 50C.

In some embodiments, The one or more pretreatment layers 104 may be conformally deposited, such as by CVD processes, including PECVD, MOCVD, ALD, cyclic deposition, or other suitable deposition processes.

For example, in some embodiments, the one or more pretreatment layers 104 are each formed using an ALD process. For example, the ALD process may use an aluminum containing precursor, such as one or more of TEA (Triethylaluminium), TMA (trimethylaluminum), and AlCl₃. In some embodiments, one or more other precursors are used. For example, at least one of TiClₓ and TaClₓ may be used. In some embodiments, the temperature is between about 250 C and about 475 C, between about 200 C and about 500 C, between about 300 C and about 425 C, or between about 350 C and about 375 C. Other temperatures may be used. In some embodiments, A soak time (or pulse time) may be less than about 60 s, about 50 s, about 40 s, about 30 s, about 20 s, or about 10 s. In some embodiments, A soak time (or pulse time) may be between about 10 s and about 40 s, about 15 s and about 30 s, about 20 s and about 25 s, about 15 s and about 25 s, about 25 s and about 30 s, or about 23 s and about 27 s. Other soak or pulse times may be used. In some embodiments, the pressure is less than about 15 T, about 14 T, about 13 T, about 12 T, about 11 T, about 10 T, about 9 T, about 8 T, about 7 T, about 6 T, or about 5 T. For example, the pressure may be between about 5 T and about 12 T, between about 6 T and about 14 T, between about 7 T and about 13 T, between about 8 T and about 12 T, or between about 9 T and about 11 T. In some embodiments, other pressures may be used. In some embodiments, all of the one or more pretreatment layers 104 are formed by using 1, 2, 3, 4, 5, 6, 7, 8, 9, 10, or more cycles of the ALD process.

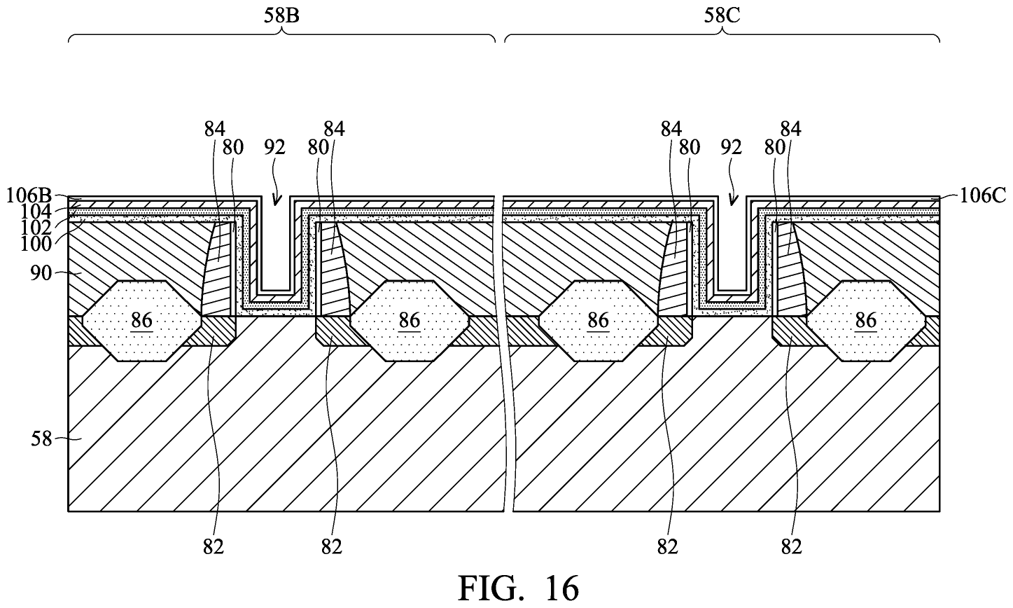

At operation 18 of the process 10 of FIG. 1, one or more conductive work function layers 106B and 106C are deposited over the one or more pretreatment layers 104 as shown in FIG. 16. One or more conductive work function layers 106B and 106C are chosen to tune the work function value of the transistor devices so that a desired threshold voltage Vt can be achieved in the transistors that is formed. Examples of materials for the one or more conductive work function layers 106B and 106C for a gate structure for n-type transistor devices include Ti, Ag, TaAl, TaAlC, TiAlN, TaC, TaCN, TaSiN, Mn, Zr, other suitable work function materials, or combinations thereof. Examples of materials for the one or more conductive work function layers 106B and 106C for p-type transistor devices include TiN, TaN, Ru, Mo, Al, WN, ZrSi2, MoSi2, TaSi2, NiSi2, WN, other suitable work function materials, or combinations thereof.

Each of the one or more conductive work function layers 106B and 106C may have a thickness selected so that a desired threshold voltage Vt can be achieved in the transistors that are formed. For example, the thickness of each of the one or more conductive work function layers 106B and 106C may have a thickness in a range from about 2.5 angstroms to about 30 angstroms. For example, the one or more conductive work function layers 106B and 106C may have a combined thickness of less than about 2.5 A. In some embodiments, the one or more conductive work function layers 106B and 106C have a combined thickness of about 2.5 A, about 5 A, about 7.5 A, about 10 A, about 12.5 A, about 15 A, about 17.5 A, about 20 A, about 22.5 A, about 25 A, about 27.5 Å, or about 30 A. In some embodiments, the one or more conductive work function layers 106B and 106C may have a combined thickness of greater than about 30 A.

In some embodiments, the one or more conductive work function layers 106B of a first N-type FinFET structure formed in region 58B has a different thickness as the one or more conductive work function layers 106B of a second N-type FinFET structure formed in region 58B. The one or more conductive work function layers 106B of the first transistor having a different thickness as the one or more conductive work function layers 106B of the second transistor may be achieved, for example, using a process which includes forming a first one or more conductive work function layers 106B over both the first and second transistors, and forming a masking layer over the first transistor and not over the second transistor. Subsequently, a second one or more conductive work function layers 106B is formed over both the first and second transistors, such that over the first transistor is the first one or more conductive work function layers 106B, the masking layer, and the second one or more conductive work function layers 106B. The masking layer is subsequently removed, where its removal causes the portion of the second one or more conductive work function layers 106B to also be removed. As a result, after performing the process, the first one or more conductive work function layers 106B is on the first transistor and the second one or more conductive work function layers 106B is not on the first transistor, and both the first and second one or more conductive work function layers 106B are on the second transistor, but not on the first transistor. Other methods may also be used to generate transistors having different thicknesses of their one or more conductive work function layers 106B. As a result of the first and second transistors having different thicknesses of their one or more conductive work function layers 106B, the first and second transistors have different threshold voltages Vt.

In some embodiments, the one or more conductive work function layers 106C of a first P-type FinFET structure formed in region 58C has a different thickness as the one or more conductive work function layers 106C of a second P-type FinFET structure formed in region 58C. The one or more conductive work function layers 106C and 106C of the first transistor having a different thickness as the one or more conductive work function layers 106C of the second transistor may be achieved, for example, using a process which includes forming a first one or more conductive work function layers 106C over both the first and second transistors, forming a masking layer over the first transistor, forming a second one or more conductive work function layers 106C over both the first and second transistors, and removing the masking layer and the portion of the second one or more conductive work function layers 106C. As a result, after performing the process, the first one or more conductive work function layers 106C is formed on the first transistor and the second one or more conductive work function layers 106C is not formed on the first transistor, and both the first and second one or more conductive work function layers 106C are formed on the second transistor. Other methods may also be used to generate transistors having different thicknesses of their one or more conductive work function layers 106C. As a result of the first and second transistors having different thicknesses of their one or more conductive work function layers 106C, the first and second transistors have different threshold voltages Vt.

In some embodiments, the one or more conductive work function layers 106B of the first transistor formed in region 58B has a combined thickness which is about 0.3, about 0.4, about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, or about 2.0 times the combined thickness of the one or more conductive work function layers 106B of the second transistor formed in region 58B. Other combined thickness ratios may be used.

In some embodiments, the one or more conductive work function layers 106C of the first transistor formed in region 58C has a combined thickness which is about 0.3, about 0.4, about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, or about 2.0 times the combined thickness of the one or more conductive work function layers 106C of the second transistor formed in region 58C. Other combined thickness ratios may be used.

In some embodiments, the one or more conductive work function layers 106B of the first or second transistors formed in region 58B has a combined thickness which is about 0.3, about 0.4, about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, or about 2.0 times the combined thickness of the one or more conductive work function layers 106C of the first or second transistors formed in region 58C. Other combined thickness ratios may be used.

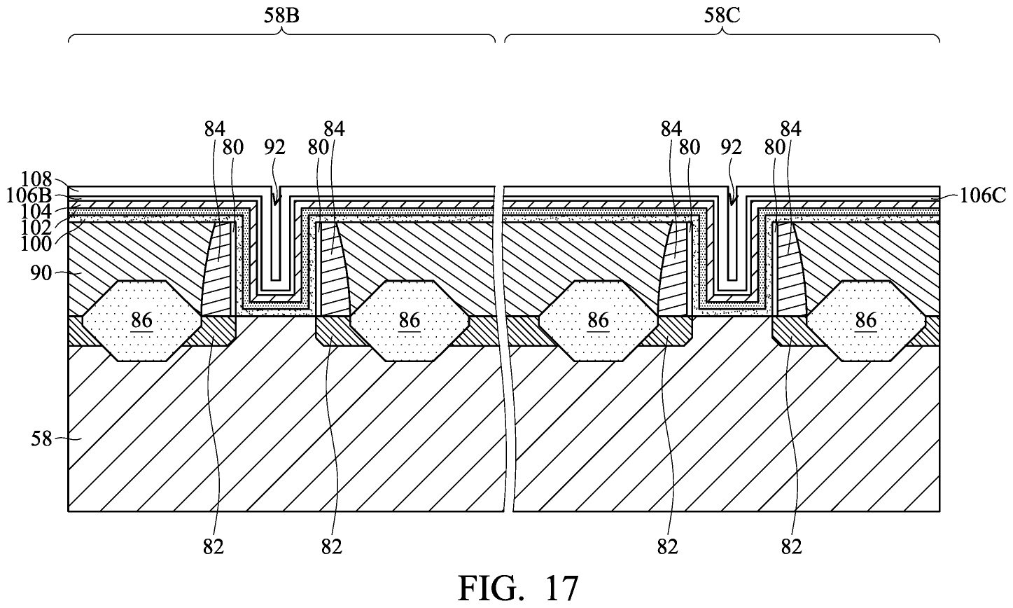

At operation 20 of the process 10 of FIG. 1, a coating or soak layer 108 is deposited over the conductive work function layers 106B and 106C, as shown in FIG. 17. In certain embodiments, the soak layer 108 comprises at least one of silicon, SiO2, or hydrogenated silicon. The soak layer 108 may be deposited by an in-situ soak process, for example, without breaking vacuum. The soak may be performed, for example, with a silicon precursor to deposit silicon by thermal decomposition, plasma decomposition, or other suitable deposition processes on one or more of conductive work function layers 106B and 106C. The silicon precursor may be silane (SiH4), disilane, trisilane, combinations thereof, or other suitable silicon precursors, or a combination thereof.

In certain embodiments, the soak layer 108 is deposited to a thickness in a range from about 0.5 A to about 15 A, such as in a range from about 3 A and about 10 A. The soak layer 108 helps to protect the conductive work function layers 106B and 106C. If the soak layer 108 is too thin, then oxygen or other contaminants may diffuse through the soak layer 108 to one or more of the layers below. If, for example, oxygen diffuses into the interfacial layer 60, the properties of the structure may be adversely impacted, such as altering a threshold voltage Vt of a transistor that is formed.

In certain embodiments, the silicon precursor is provided at a flow rate in a range from about 300 sccm to about 500 sccm. In some embodiments, an additional process gas and/or carrier gas may also be provided, such as hydrogen gas. In certain embodiments, the soak is performed at a temperature in a range from about 350° C. to about 475° C. at a pressure in a range from about 12 torr to about 25 torr. If a temperature too low is used during the silicon precursor soak, the silicon precursor may not sufficiently decompose to form a silicon layer over the conductive work function layers 106B and 106C. For example, the formation of a layer of silicon, SiO2, or hydrogenated silicon may form by the following reaction in formula (I):

SiH4 (g)→Si (s)+2H2 (g) (I)

If a temperature to high is used during the silicon precursor soak, it may be difficult to control the deposition rate of the silicon material.

In certain embodiments, a silicon precursor is provided at a flow rate for a duration in a range from about 100 s to about 600 s.

In some embodiments, the duration is dependent on a combined thickness of the conductive work function layers 106B and 106C. Accordingly, the thickness of the soak layer 108 may be related to the combined thickness of the conductive work function layers 106B and 106C. For example, for transistors having a relatively smaller combined thickness of the conductive work function layers 106B and 106C, the duration of the silicon precursor, and therefore, the thickness of the coating layer is relatively increased, and for transistors having a relatively greater combined thickness of the conductive work function layers 106B and 106C, the duration of the silicon precursor, and therefore, the thickness of the coating layer soak layer 108 is relatively decreased.

For example, in some embodiments, in a first transistor, the combined thickness of either of conductive work function layers 106B and 106C is about 5 A and the thickness of the soak layer 108 is about 10 A, and in a second transistor, the combined thickness of either of conductive work function layers 106B and 106C is about 10 A and the thickness of the soak layer 108 is about 5 A. In some embodiments, in a first transistor, the combined thickness of conductive work function layers 106B or 106C is about 5 A and the duration of providing the silicon precursor is about 500 s, and in a second transistor, the combined thickness of conductive work function layers 106B or 106C is about 10 A and the duration of providing the silicon precursor is about 200 s.

In certain embodiments, one or more, or all of steps of operations 18 and 20 are performed within the same integrated process system without exposing the structure to the ambient environment or to air. In some embodiments, steps of operation 18 and 20 may be performed in the same processing chamber, or in-situ with one process recipe to perform the operation 18 to deposit the conductive work function layers 106B and 106C and another process recipe to perform the operation 20 to deposit the soak layer 108.

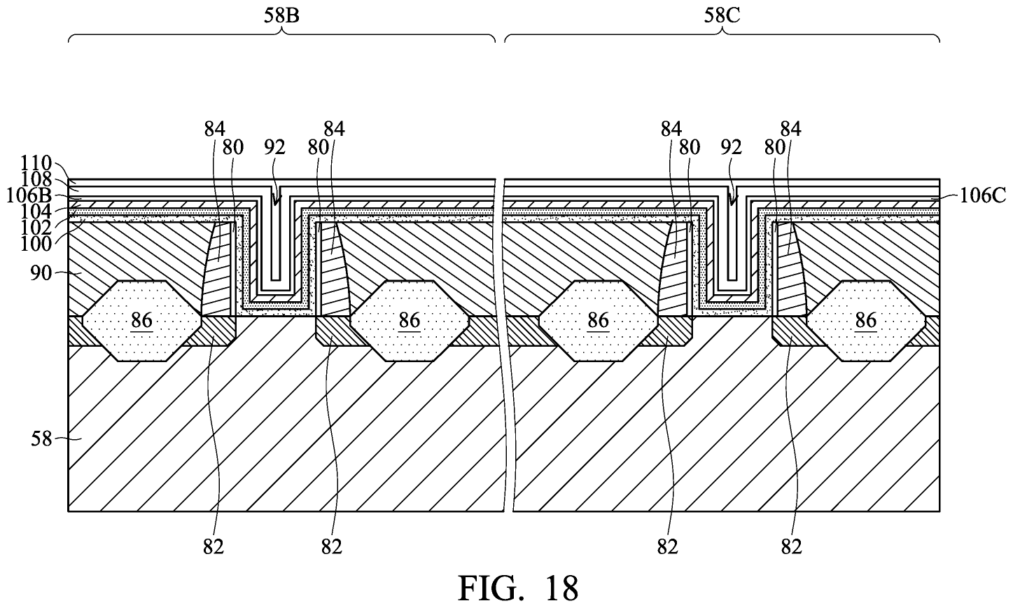

At operation 22 of the process 10 of FIG. 1, a fill metal layer 110 is deposited over the soak layer 108, as shown in FIG. 18. In certain embodiments, the fill metal layer 110 may comprise Titanium, TiN, Tantalum, TaN, TaC, tungsten, cobalt, aluminum, ruthenium, copper, other suitable metals, multi-layers thereof, a combination thereof, multiple layers thereof, or the like. The fill metal layer 110 may be deposited by a suitable process, such as CVD, physical vapor deposition (PVD), sputtering, ALD, PECVD, plating, or other deposition processes.

In some embodiments, a glue metal layer (not shown) may be deposited, for example, by ALD, CVD, PVD, and/or other suitable process, on the soak layer 108, and the fill metal layer 110 is deposited on the glue layer. The glue layer may serve multiple purposes. For example, the glue layer uses materials that promote or enhance adhesion to the fill metal layer 110, which is to be formed on the glue layer. The glue layer may also provide a desired work function and adjust Vt of the subsequent transistor.

In some embodiments, a first glue layer for p-type FinFETs comprises a p-type work function metal layer, and a second glue layer for n-type FinFETs comprises an n-type work function metal layer. In some embodiments, a same glue layer is used for both p-type and n-type FinFETs. In some embodiments, only one of p-type and n-type FinFETs use a glue layer.

In an embodiment, the glue layer has a relatively small thickness (e.g., less than 3 nm, or about 2 nm to about 3 nm) over the fins in order to achieve a designed work function for the FinFET. In some embodiments, the glue layer may be thicker on one of p-type and n-type FinFETs, and thinner on the other of p-type and n-type FinFETs.

The choice of metal and thickness to be used in the glue layer may be determined or influenced by an overall threshold voltage desired for the FinFET device being formed.

Exemplary p-type work function metals include Ti, TiN, TaN, Ru, Mo, Al, WN, ZrSi2, MOSi2, TaSi2, NiSi2, WN, and/or combinations thereof, and exemplary n-type work function metals include Ti, Ag, TaAl, TaAlC, TiAlN, TaC, TaCN, TaSiN, Mn, Zr, and/or combinations thereof. In some embodiments, the glue layer does not significantly impact the work function (e.g., by keeping the glue metal layer relatively thin), because the work function are substantially determined by the conductive work function layers 106B and 106C.

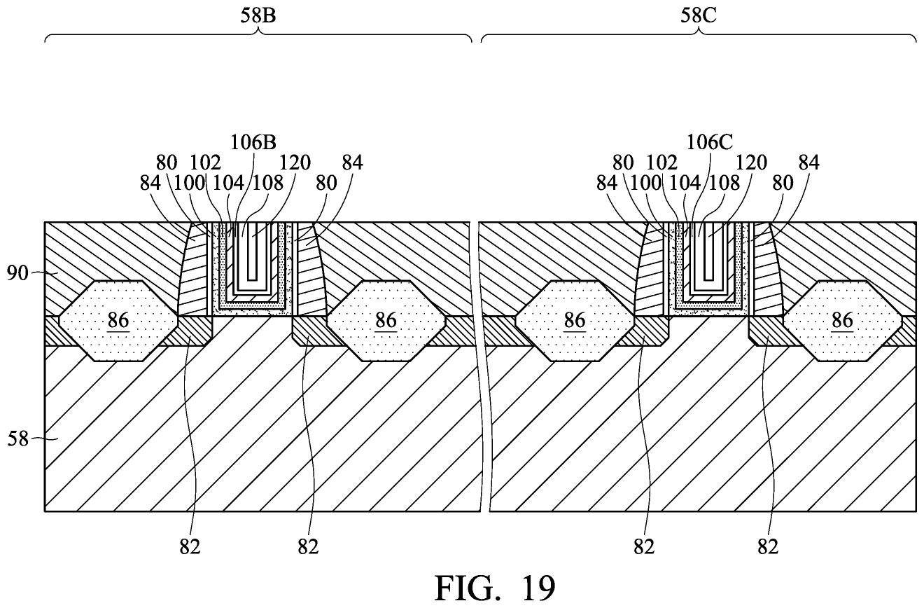

Also at operation 22 of the process 10 of FIG. 1, a planarization process, such as a CMP, is performed to remove the excess portions of the interface layer 100, gate dielectric layer 102, and fill metal layer 110, which excess portions are over the top surface of the ILD 90, as shown in FIG. 19. The remaining portions of the fill metal layer 110 form gate electrodes 120, which in combination with the other layers, form replacement gates of the resulting FinFETs. The interface layer 100, gate dielectric layer 102, capping layer 116, and gate electrodes 120 may be collectively referred to as the “gates” or “gate stacks” of the resulting FinFETs. The gate stacks may extend along sidewalls of the channel region of the fins 58.

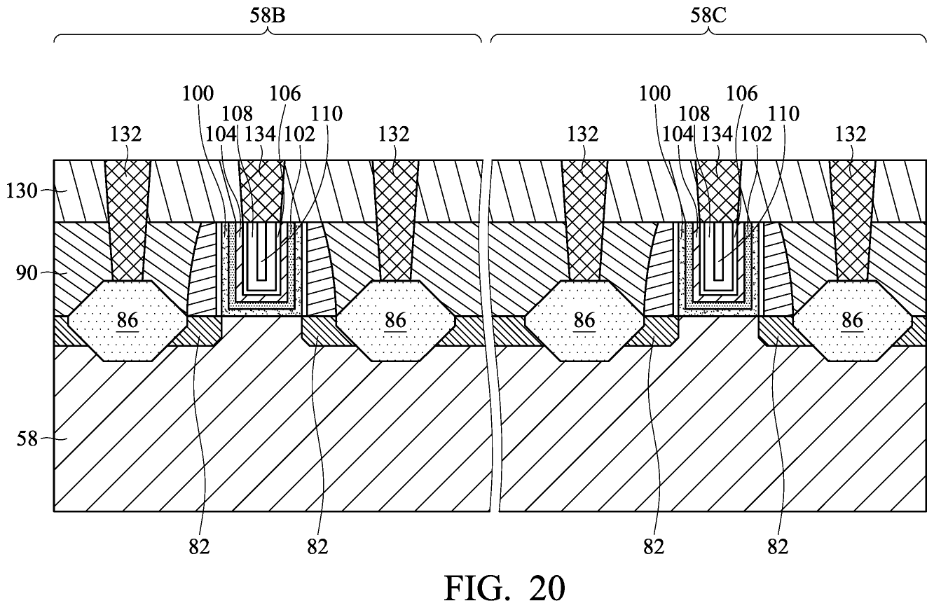

At operation 24 of the process 100 of FIG. 1, the structure may be further processed as shown in FIG. 20. An ILD 130 is formed over the gate stacks and ILD 90. In an embodiment, the ILD 130 is a flowable film formed by a flowable CVD method. In some embodiments, the ILD 130 is formed of a dielectric material such as PSG, BSG, BPSG, USG, or the like, and may be deposited by any suitable method, such as CVD and PECVD.

Source/drain contacts 132 and gate contacts 134 are formed through the ILDs 90 and 130. Openings for the source/drain contacts 132 are formed through the ILDs 90 and 130, and openings for the gate contacts 134 are formed through the ILD 130. The openings may be formed using acceptable photolithography and etching techniques. A liner, such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the ILD 130. The remaining liner and conductive material form the source/drain contacts 132 and gate contacts 134 in the openings. An anneal process may be performed to form a silicide at the interface between the epitaxial source/drain regions 86 and the source/drain contacts 132. The source/drain contacts 132 are physically and electrically coupled to the epitaxial source/drain regions 86, and the gate contacts 134 are physically and electrically coupled to the gate electrodes 120. The source/drain contacts 132 and gate contacts 134 may be formed in different processes, or may be formed in the same process. Although shown as being formed in the same cross-sections, it should be appreciated that each of the source/drain contacts 132 and gate contacts 134 may be formed in different cross-sections, which may avoid shorting of the contacts.

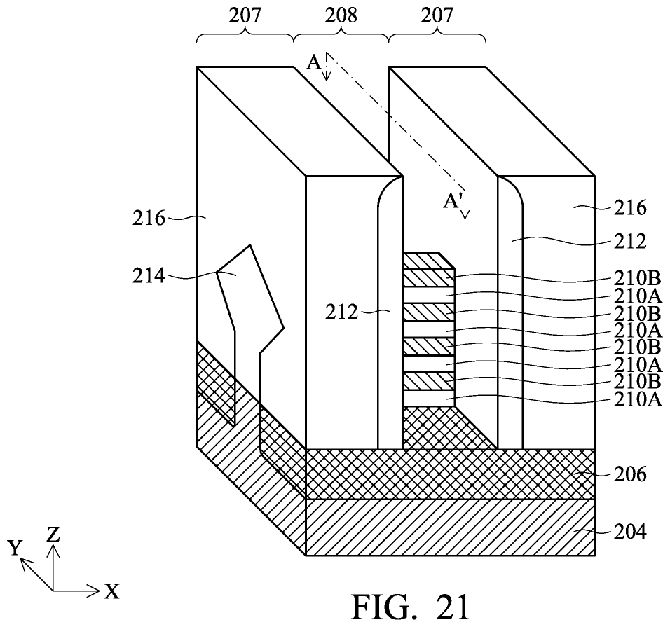

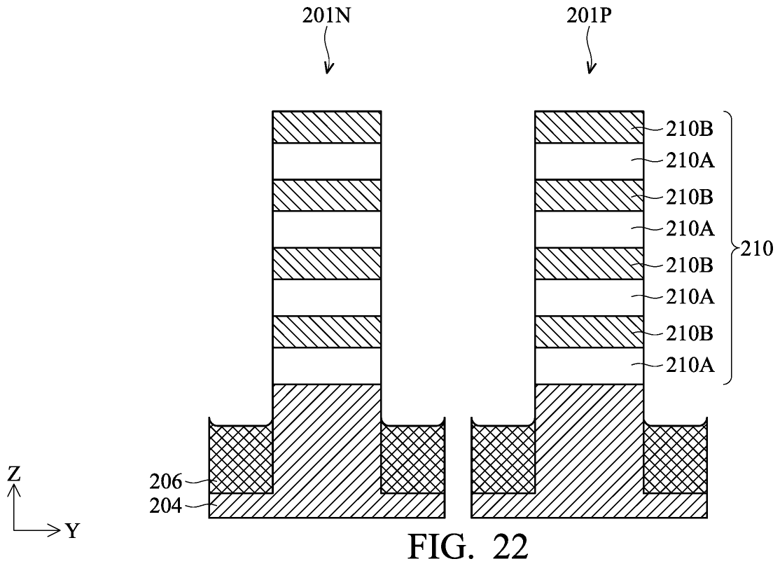

FIG. 21 is a three-dimensional view of an initial semiconductor structure for a nanostructure semiconductor device (for example, device 201N or 201P) formed at operation 12 of method 10. FIG. 22 is a cross-section view along plane A-A′ in FIG. 21 for the semiconductor devices 201N and 201P. In the illustrated example, device 201N is for an n-type FET and device 201P is a p-type device.

Referring to FIGS. 21 and 22, the initial semiconductor structure is formed on a substrate 204. The substrate 204 is a bulk substrate that includes silicon. Alternatively or additionally, the bulk substrate includes another elementary semiconductor, such as germanium (Ge); a compound semiconductor, such as silicon carbide (SiC), silicon phosphide (SiP), gallium arsenide (GaAs), gallium phosphide (GaP), indium phosphide (InP), indium arsenide (InAs), indium antimonide (InSb), zinc oxide (ZnO), zinc selenide (ZnSe), zinc sulfide (ZnS), zinc telluride (ZnTe), cadmium selenide (CdSe), cadmium sulfide (CdS), and/or cadmium telluride (CdTe); an alloy semiconductor, such as SiGe, SiPC, GaAsP, AlInAs, AlGaAs, GaInAs, GaInP, and/or GaInAsP; other group III-V materials; other group II-IV materials; or combinations thereof. In some embodiments, the substrate 204 may include indium tin oxide (ITO) glass, include silicon on insulator (SOI) substrate, be strained and/or stressed for performance enhancement.

The substrate 204 may include various doped regions. In some embodiments, the substrate 204 includes n-type doped regions (for example, n-type wells) doped with n-type dopants, such as phosphorus (for example, 31P), arsenic, other n-type dopant, or combinations thereof. In some embodiments, the substrate 204 includes p-type doped region (for example, p-type wells) doped with p-type dopants, such as boron (for example, 11B, BF2), indium, other p-type dopant, or combinations thereof. In some embodiments, the substrate 204 includes doped regions formed with a combination of p-type dopants and n-type dopants. The various doped regions can be formed directly on and/or in the substrate 204, for example, providing a p-well structure, an n-well structure, a dual-well structure, a raised structure, or combinations thereof. An ion implantation process, a diffusion process, and/or other suitable doping process can be performed to form the various doped regions.

The semiconductor structure may also comprise a semiconductor layer stack 210 (hereinafter, stack 210) formed over the substrate 204. In the depicted embodiment, the stack 210 includes alternating semiconductor layers, such as first semiconductor layers 210A including a first semiconductor material and second semiconductor layers 210B including a second semiconductor material that is different from the first semiconductor material. The different semiconductor materials in the semiconductor layers 210A and 210B have different oxidation rates and/or different etch selectivity. In some embodiments, the second semiconductor material of the second semiconductor layers 210B is the same as the substrate 204. For example, the first semiconductor layers 210A comprise silicon germanium (SiGe), and the second semiconductor layers 210B comprise Si (like the substrate 204). Thus, the stack 210 is arranged with alternating SiGe/Si/SiGe/Si/ . . . layers from bottom to top. In some embodiments, the material of the top semiconductor layer may or may not be the same as the bottom semiconductor layer in the stack. For example, for a stack that includes alternating SiGe and Si layers, the bottom semiconductor layer comprises SiGe, and the top semiconductor layer may comprise Si or SiGe. In the depicted embodiment, the bottom semiconductor layer 210A comprises SiGe, while the top semiconductor layer 210B comprises Si. In some embodiments, the second semiconductor layers 210B may be undoped or substantially dopant-free. In other words, no intentional doping is performed when forming the second semiconductor layers 210B. In some other embodiments, the semiconductor layers 210B may be doped with a p-type dopant, such as boron (B, 11B or BF2), gallium (Ga), or combinations thereof, or an n-type dopant, such as phosphorus (P, 31P), arsenic (As), or combinations thereof. The number of the semiconductor layers 210A and 210B in the stack 210 is not limited. For example, the stack 210 may comprise one to ten layers of semiconductor layers 210A or 210B each. In some embodiments, different semiconductor layers 210A and 210B in the stack 210 have the same thickness in the Z-direction. In some other embodiments, different semiconductor layers 210A and 210B in the stack 210 have different thicknesses.

The stack 210 is formed over the substrate 204 using any suitable process. In some embodiments, the semiconductor layers 210A and/or 210B are formed by suitable epitaxy process. For example, semiconductor layers comprising SiGe and Si are formed alternately over the substrate 204 by a molecular beam epitaxy (MBE) process, a chemical vapor deposition (CVD) process, such as a metal organic CVD (MOCVD) process, and/or other suitable epitaxial growth processes. Thereafter, a photoresist and an etching process may be performed to the semiconductor layers to form the stack 210 (comprising semiconductor layers 210A and 210B) in a fin-shape as illustrated in FIG. 22. The fin-shape stack 210 extends along the X-direction and comprises a channel region 208, a source region, and a drain region (hereinafter both referred to as S/D regions 207) (FIG. 21). The S/D regions 207 are interposed by the channel region 208. As illustrated in FIG. 21, the plane A-A′ is taken in the channel region 208 of the stack 210.

The semiconductor structures also include an isolation feature 206 formed over the substrate 204 to separate and isolate the active regions. In some embodiments, one or more dielectric materials, such as silicon dioxide (SiO2) and/or silicon nitride (Si3N4), is deposited over the substrate 204 along sidewalls of the stack 210. The dielectric material may be deposited by CVD, plasma enhanced CVD (PECVD), physical vapor deposition (PVD), thermal oxidation, or other techniques. Subsequently, the dielectric material is recessed (for example, by etching) to form the isolation feature 206. In some embodiments, a top surface of the isolation feature 206 is substantially coplanar with or lower than a bottom surface of the lowermost first semiconductor layer 210A, as depicted in FIGS. 21 and 22.

The semiconductor structure also includes gate spacers 212 formed over the stack 210. In some embodiments, the gate spacers 212 comprise a dielectric material, such as silicon dioxide (SiO2), silicon nitride (Si3N4), silicon oxynitride (SiON), or silicon carbide (SiC). The gate spacers 212 are formed by any suitable process. For example, first, a dummy gate stack (comprising polysilicon, not shown) is formed over the channel region 208 of the stack 210. A spacer layer comprising the dielectric material is then deposited (for example, by atomic layer deposition (ALD), CVD, PVD, or other proper process) over the substrate 204 and the dummy gate stack. Subsequently, the spacer layer is anisotropically etched to remove the portions in the X-Y plane (the plane in which the top surface of the substrate 204 is). The remaining portions of the spacer layer become the gate spacers 212.

Thereafter, S/D regions 207 of the stack 210 may be recessed along sidewalls of the gate spacers 212, and inner spacers (not shown) are formed between edges of the semiconductor layers 210B. In some embodiments, S/D regions 207 of the stack 210 are recessed by a S/D etching process performed along the gate spacers 212 to form S/D trenches. The S/D etching process may be a dry etch, a wet etch, or combinations thereof. A time control is performed to the S/D etching process, such that the sidewalls of each semiconductor layers 210A and 210B are exposed in the S/D trenches. Thereafter, portions (edges) of the semiconductor layers 210A exposed in the S/D trenches are selectively removed by a suitable etching process to form gaps between adjacent semiconductor layers 210B. In other words, edges of the semiconductor layers 210B are suspended in the S/D regions 207. Subsequently, inner spacers (not shown) are formed to fill in the gaps between the adjacent semiconductor layers 210B. The inner spacers comprise a dielectric material that is similar to the material of the gate spacers, such as SiO2, Si3N4, SiON, SiC, or combinations thereof. The dielectric material of the inner spacers may be deposited in the S/D trenches and in the gaps between the semiconductor layers 210B by CVD, PVD, ALD, or combinations thereof. Extra dielectric material is removed along sidewalls of the gate spacers 212 until the sidewalls of the semiconductor layers 210B are exposed in the S/D trenches.

Thereafter, epitaxial S/D features 214 are formed in the S/D regions 207 of the stack 210. In some embodiments, the epitaxial S/D features 214 may include a semiconductor material such as silicon (Si) or germanium (Ge); a compound semiconductor such as silicon germanium (SiGe), silicon carbide (SiC), gallium arsenide (GaAs), etc.; an alloy semiconductor; or combinations thereof. An epitaxy process may be implemented to epitaxially grow S/D features 214. The epitaxy process may include CVD deposition (for example, vapor-phase epitaxy (VPE), ultra-high vacuum CVD (UHV-CVD), low-pressure CVD (LPCVD), and/or plasma-enhanced (PECVD)), molecular beam epitaxy (MBE), other suitable selective epitaxial growth (SEG) processes, or combinations thereof. Epitaxial S/D features 214 may be doped with n-type dopants and/or p-type dopants. In some embodiments, epitaxial S/D features 214 may include multiple epitaxial semiconductor layers, and different epitaxial semiconductor layers are different in amount of dopant included therein.

The semiconductor structure also includes an interlayer dielectric (ILD) layer 216 formed over the substrate 204. As illustrated in FIG. 21, the ILD 216 is disposed along the gate spacers 212 and covers the isolation feature 206 and the epitaxial S/D features 214. In some embodiments, the ILD layer 216 includes a low-k dielectric material, such as tetraethylorthosilicate (TEOS), undoped silicate glass, or doped silicon oxide such as borophosphosilicate glass (BPSG), fluorosilicate glass (FSG), phosphosilicate glass (PSG), boron doped silicon glass (BSG), other suitable dielectric materials, or combinations thereof. The ILD layer 216 may include a multi-layer structure having multiple dielectric materials and may be formed by a deposition process such as CVD, flowable CVD (FCVD), spin-on-glass (SOG), other suitable methods, or combinations thereof. In some embodiments, an etch stop layer (ESL, not shown) including dielectric material(s) (such as SiO2, SiON, Si3N4, SiCN, SiOC, SiOCN) may be deposited between the ILD layer 216 and the isolation feature 206 and between the ILD layer 216 and the epitaxial S/D features 214.

After the formation of the ILD layer 216, the dummy gate stack may be removed to form a gate trench that exposes the channel region 208 of the stack 210. In some embodiments, removing the dummy gate stack includes one or more etching processes, such as wet etching, dry etching, reactive-ion etching (RIE), or other etching techniques.

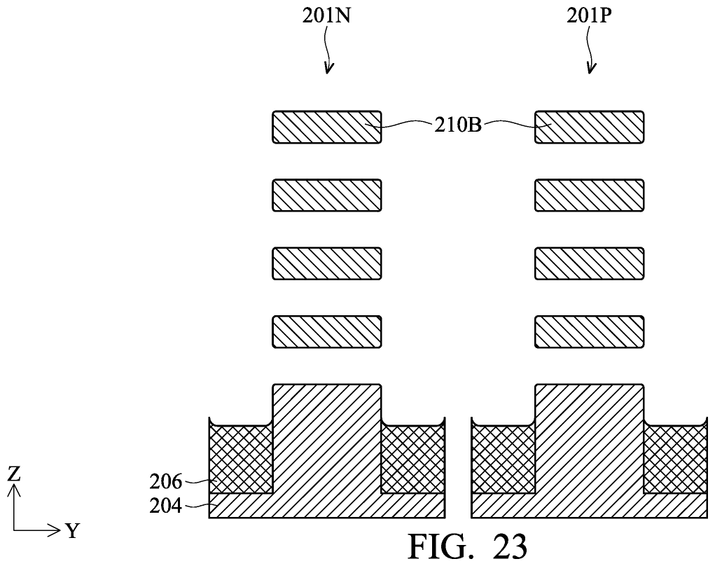

Now referring to FIGS. 1 and 23, also at operation 12, a channel release process is performed, such that the semiconductor layers 210A are removed from the gate trench. As a result, the semiconductor layers 210B are suspended in the channel region. The suspended semiconductor layers 210B (also referred to as channel semiconductor layers) are collectively referred to as a stack structure. The semiconductor layers 210A are removed by a selective etching process that is tuned to remove only the semiconductor layers 210A while the semiconductor layers 210B remain substantially unchanged. The selective etching may be a selective wet etching, a selective dry etching, or a combination thereof. In some embodiments, the selective wet etching process may include a hydro fluoride (HF) or NH₄OH etchant. In some embodiments, the selective removal of semiconductor layers 210A may include an oxidation process followed by oxidation removal. For example, the SiGe oxidation process may include forming and patterning various masking layers such that the oxidation is controlled to the SiGe layers 210A. In other embodiments, the SiGe oxidation process is a selective oxidation due to the different compositions of the semiconductor layers 210A and 210B. In some examples, the SiGe oxidation process may be performed by exposing the structure to a wet oxidation process, a dry oxidation process, or a combination thereof. Thereafter, the oxidized semiconductor layers 210A, which include SiGeOx, are removed by an etchant such as NH4OH or diluted HF.

As depicted in FIG. 23, each of the stack structures includes the channel semiconductor layers 210B separated from each other and stacked up along a direction (Z-direction) generally perpendicular to a top surface of the substrate 204 (X-Y plane). In some embodiments, the semiconductor layers 210B are slightly etched or not etched during the operation 12. Further, semiconductor layers 210B may be of any suitable shapes, such as a wire-like shape, a sheet-like shape, or other geometrical shape (for other stack structure transistors). Each of the semiconductor layers 210B has a thickness Ti in the Z-direction, and the adjacent suspended semiconductor layers 210B are separated with a space S1 in the Z-direction. In some embodiments, the thickness T1 is about 3 nm to about 20 nm. In some embodiments, the space Si is about 5 nm to about 15 nm.

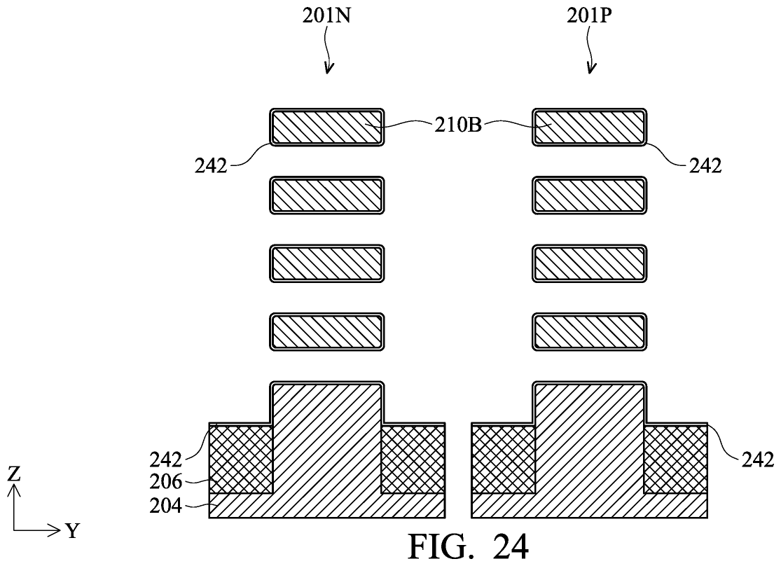

Now referring to FIGS. 1 and 24, at operation 14, interfacial layers 242 are formed around the semiconductor layers 210B of the transistors 201N and 201P. In some embodiments, the interfacial layers 242 are also formed over the substrate 204 and the isolation feature 206. A material of the interfacial layers 242 may include materials such as SiO2, SiON, HfSiO, other suitable materials, or combinations thereof. A deposition process may be performed to form the interfacial layers 242 wrapping around the suspended semiconductor layers 210B. The deposition process may include CVD, PVD, ALD, other suitable methods, or combinations thereof. In some other embodiments, the interfacial layers 242 are formed by an oxidation process. For example, in the case that the semiconductor layers 210B include silicon, the structure may be exposed to a wet oxidation process, a dry oxidation process, or a combination thereof. Thereby, a thin layer including SiO2 is formed around each of the semiconductor layers 210B and functions as a interfacial layer 242. A thickness T3 (in the Z-direction) of the interfacial layers 242 is about 6 A to about 15 A.

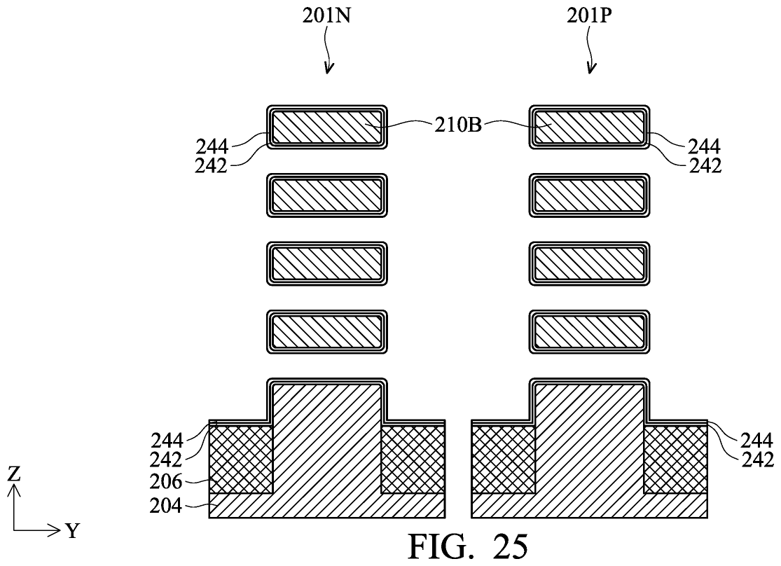

Now referring to FIGS. 1 and 25, also at operation 14, gate dielectric layers 244 are formed around the interfacial layers 242. In some embodiments, the gate dielectric layers 244 include a high-k dielectric material such as Si3N4, SiO2, hafnium oxide (HfO), zirconium oxide, lanthanum oxide, titanium oxide, yttrium oxide, strontium titanite, other suitable metal-oxides, or combinations thereof. In some embodiments, the gate dielectric layers 244 are deposited by ALD and/or other suitable methods. In some embodiments, a thickness T4 (in the Z-direction) of the gate dielectric layers 244 is about 15 A to about 18 A. The thickness T4 cannot be too thin or too thick. If it is too thin, it might break easily. If it is too thick, it would occupy too much space.

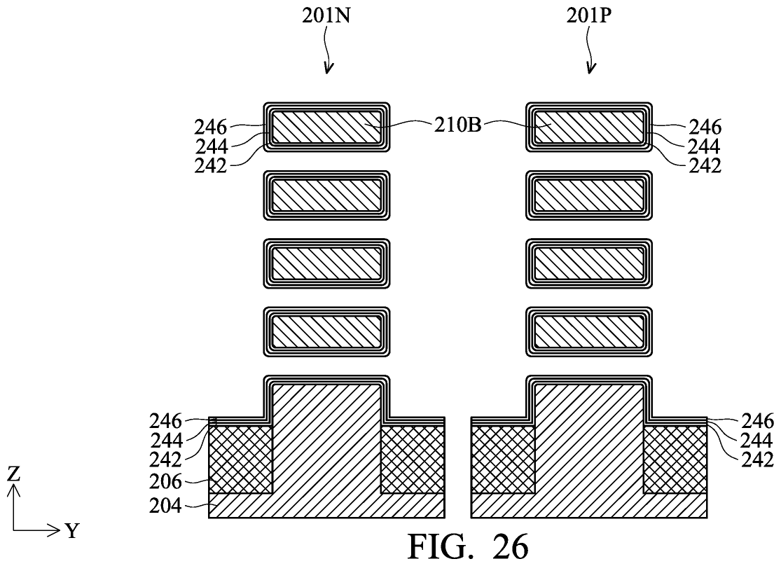

Now referring to FIGS. 1 and 26, at operation 16, one or more pretreatment layers 246 are deposited over the gate dielectric layers 244. One or more pretreatment layers 246 are used to pretreat the gate dielectric layers 244 so that, for example, an acceptable Dit can be achieved in the transistors that are formed. Examples of a pretreatment layers 246 for the transistors include Al-based alloy, Al-based metal carbide or Al-based metal nitride such as TaAl, TaAlC, TaAlN, or TiAl, TiAlC or TiAlN, AlOxCy (e.g. with C less than about 30%, about 25%, about 20%, about 15%, or about 10%), other suitable pretreatment layer materials, or combinations thereof.

The one or more pretreatment layers 246 may have a combined thickness in a range from about 2.5 angstroms to about 30 angstroms. For example, the one or more pretreatment layers 246 may have a combined thickness of less than about 2.5 A. In some embodiments, the one or more pretreatment layers 246 has a combined thickness of about 2.5 A, about 5 A, about 7.5 A, about 10 A, about 12.5 A, about 15 A, about 17.5 A, about 20 A, about 22.5 A, about 25 A, about 27.5 Å, or about 30 A. In some embodiments, the one or more pretreatment layers 246 may have a combined thickness of greater than about 30 A. In some embodiments, the one or more pretreatment layers 246 of the transistor 201N has the same or substantially the same thickness as the one or more pretreatment layers 246 of the 201P. In some embodiments, the one or more pretreatment layers 246 of the transistor 201N has a different thickness as the one or more pretreatment layers 246 of the transistor 201P.

In some embodiments, The one or more pretreatment layers 246 may be conformally deposited, such as by processes, including PECVD, MOCVD, ALD, cyclic deposition, or other suitable deposition processes, and masking.

For example, in some embodiments, the one or more pretreatment layers 246 are each formed using an ALD process. For example, the ALD process may use an aluminum containing precursor, such as one or more of TEA (Triethylaluminium), TMA (trimethylaluminum), and AlCl₃. In some embodiments, one or more other precursors are used. For example, at least one of TiClₓ and TaClₓ may be used. In some embodiments, the temperature is between about 250 C and about 475 C, between about 200 C and about 500 C, between about 300 C and about 425 C, or between about 350 C and about 375 C. Other temperatures may be used. In some embodiments, A soak time (or pulse time) may be less than about 60 s, about 50 s, about 40 s, about 30 s, about 20 s, or about 10 s. In some embodiments, A soak time (or pulse time) may be between about 10 s and about 40 s, about 15 s and about 30 s, about 20 s and about 25 s, about 15 s and about 25 s, about 25 s and about 30 s, or about 23 s and about 27 s. Other soak or pulse times may be used. In some embodiments, the pressure is less than about 15 T, about 14 T, about 13 T, about 12 T, about 11 T, about 10 T, about 9 T, about 8 T, about 7 T, about 6 T, or about 5 T. For example, the pressure may be between about 5 T and about 12 T, between about 6 T and about 14 T, between about 7 T and about 13 T, between about 8 T and about 12 T, or between about 9 T and about 11 T. Other pressures may be used. In some embodiments, A soak time (or pulse time) may be less than about 30 s. Other soak or pulse times may be used. In some embodiments, the pressure is less than about 10 Torr. In some embodiments, other pressures may be used. In some embodiments, all of the one or more pretreatment layers 246 are formed by using 1, 2, 3, 4, 5, 6, 7, 8, 9, 10, or more cycles of the ALD process.

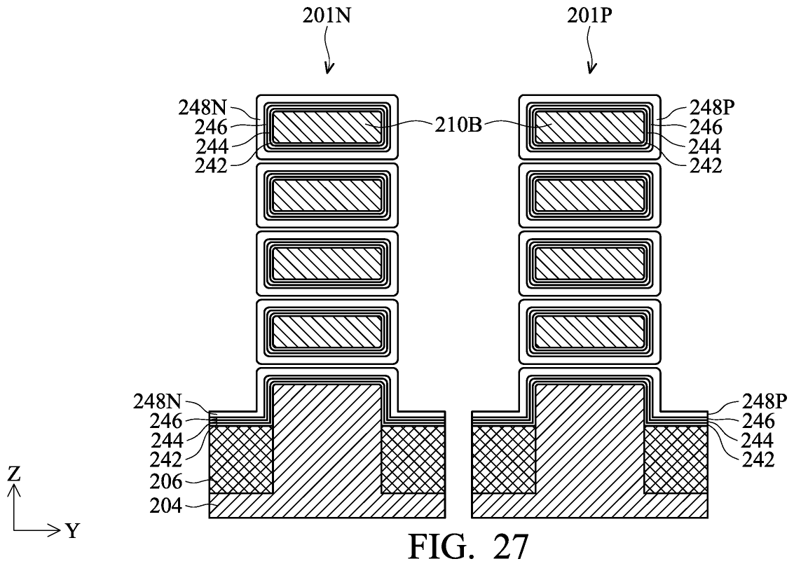

Now referring to FIGS. 1 and 27, at operation 18, one or more conductive work function layers 248N and 248P are deposited over the one or more pretreatment layers 246. One or more conductive work function layers 248N and 248P are chosen to tune the work function value of the transistor devices so that a desired threshold voltage Vt can be achieved in the transistors that is formed. Examples of materials for the one or more conductive work function layers 248N and 248P for a gate structure for n-type transistor devices include Ti, Ag, TaAl, TaAlC, TiAlN, TaC, TaCN, TaSiN, Mn, Zr, other suitable work function materials, or combinations thereof. Examples of materials for the one or more conductive work function layers 248N and 248P for p-type transistor devices include TiN, TaN, Ru, Mo, Al, WN, ZrSi2, MoSi2, TaSi2, NiSi2, other suitable work function materials, or combinations thereof.

Each of the one or more conductive work function layers 248N and 248P may have a thickness selected so that a desired threshold voltage Vt can be achieved in the transistors that are formed. For example, the thickness of each of the one or more conductive work function layers 248N and 248P may have a thickness in a range from about 2.5 angstroms to about 30 angstroms. For example, the one or more conductive work function layers 248N and 248P may have a combined thickness of less than about 2.5 A. In some embodiments, the one or more conductive work function layers 248N and 248P have a combined thickness of about 2.5 A, about 5 A, about 7.5 A, about 10 A, about 12.5 A, about 15 A, about 17.5 A, about 20 A, about 22.5 A, about 25 A, about 27.5 A, or about 30 A. In some embodiments, the one or more conductive work function layers 248N and 248P may have a combined thickness of greater than about 30 A.

In some embodiments, the one or more conductive work function layers 248N of a first n-type transistor structure has a different thickness as the one or more conductive work function layers 248N of a second n-type transistor structure. The one or more conductive work function layers 248N and 248P of the first n-type transistor having a different thickness as the one or more conductive work function layers 248N of the second n-type transistor may be achieved, for example, using a process which includes forming a first one or more conductive work function layers 248N over both the first and second transistors, forming a masking layer over the first transistor, forming a second one or more conductive work function layers 248N over both the first and second transistors, and removing the masking layer and the portion of the second one or more conductive work function layers 248N. As a result, after performing the process, the first one or more conductive work function layers 248N is formed on the first transistor and the second one or more conductive work function layers 248N is not formed on the first transistor, and both the first and second one or more conductive work function layers 248N are formed on the second transistor. Other methods may also be used to generate transistors having different thicknesses of their one or more conductive work function layers 248N. As a result of the first and second n-type transistors having different thicknesses of their one or more conductive work function layers 248N, the first and second n-type transistors have different threshold voltages Vt.

In some embodiments, the one or more conductive work function layers 248P of a first p-type transistor structure has a different thickness as the one or more conductive work function layers 248P of a second p-type transistor structure. The one or more conductive work function layers 248P and 248P of the first p-type transistor having a different thickness as the one or more conductive work function layers 248P of the second p-type transistor may be achieved, for example, using a process which includes forming a first one or more conductive work function layers 248P over both the first and second transistors, forming a masking layer over the first transistor, forming a second one or more conductive work function layers 248P over both the first and second transistors, and removing the masking layer and the portion of the second one or more conductive work function layers 248P. As a result, after performing the process, the first one or more conductive work function layers 248P is formed on the first transistor and the second one or more conductive work function layers 248P is not formed on the first transistor, and both the first and second one or more conductive work function layers 248P are formed on the second transistor. Other methods may also be used to generate transistors having different thicknesses of their one or more conductive work function layers 248P. As a result of the first and second p-type transistors having different thicknesses of their one or more conductive work function layers 248P, the first and second p-type transistors have different threshold voltages Vt.

In some embodiments, the one or more conductive work function layers 248N of the first n-type transistor has a combined thickness which is about 0.3, about 0.4, about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, or about 2.0 times the combined thickness of the one or more conductive work function layers 248N of the second n-type transistor. Other combined thickness ratios may be used.

In some embodiments, the one or more conductive work function layers 248P of the first p-type transistor has a combined thickness which is about 0.3, about 0.4, about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, or about 2.0 times the combined thickness of the one or more conductive work function layers 248P of the second p-type transistor. Other combined thickness ratios may be used.

In some embodiments, the one or more conductive work function layers 248N of the first or second n-type transistors has a combined thickness which is about 0.3, about 0.4, about 0.5, about 0.6, about 0.7, about 0.8, about 0.9, about 1.0, about 1.1, about 1.2, about 1.3, about 1.4, about 1.5, about 1.6, about 1.7, about 1.8, about 1.9, or about 2.0 times the combined thickness of the one or more conductive work function layers 248P of the first or second p-type transistors. Other combined thickness ratios may be used.

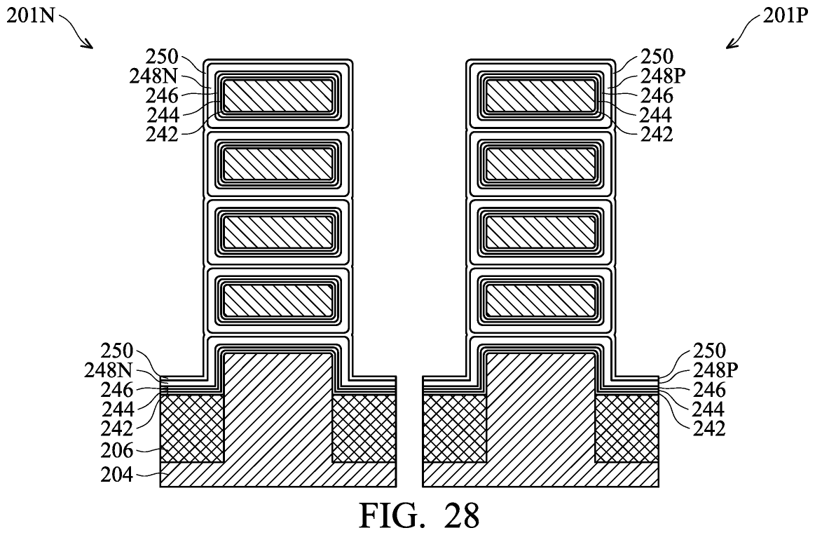

Now referring to FIGS. 1 and 28, at operation 20, a coating or soak layer 250 is deposited over the conductive work function layers 248N and 248P, and fill the remaining gaps between semiconductor layers 210B. In certain embodiments, the soak layer 250 comprises at least one of silicon, SiO2, or hydrogenated silicon. The soak layer 250 may be deposited by an in-situ soak process, for example, without breaking vacuum. The soak may be performed, for example, with a silicon precursor to deposit silicon by thermal decomposition, plasma decomposition, or other suitable deposition processes on one or more of conductive work function layers 248N and 248P. The silicon precursor may be silane (SiNH4), disilane, trisilane, combinations thereof, or other suitable silicon precursors, or a combination thereof.

In certain embodiments, the soak layer 250 is deposited to a thickness in a range from about 0.5 A to about 15 A, such as in a range from about 3 A and about 10 A. The soak layer 250 helps to protect the conductive work function layers 248N and 248P. The soak layer 250 is thick enough that oxygen or other contaminants do not or substantially do not diffuse through the soak layer 250 to one or more of the layers below. If, for example, oxygen diffuses into the interfacial layer 60, the properties of the structure may be adversely impacted, such as altering a threshold voltage Vt of a transistor that is formed.

In certain embodiments, the silicon precursor is provided at a flow rate in a range from about 300 sccm to about 500 sccm. In some embodiments, an additional process gas and/or carrier gas may also be provided, such as hydrogen gas. In certain embodiments, the soak is performed at a temperature in a range from about 350° C. to about 475° C. at a pressure in a range from about 12 torr to about 25 torr. If a temperature too low is used during the silicon precursor soak, the silicon precursor may not sufficiently decompose to form a silicon layer over the conductive work function layers 248N and 248P. For example, the formation of a layer of silicon, SiO2, or hydrogenated silicon may form by the following reaction in formula (I):

SiH4 (g)→Si (s)+2H2 (g) (I)

If a temperature to high is used during the silicon precursor soak, it may be difficult to control the deposition rate of the silicon material.

In certain embodiments, a silicon precursor is provided at a flow rate for a duration in a range from about 100 s to about 600 s.

In some embodiments, the duration is dependent on a combined thickness of the conductive work function layers 248N and 248P. Accordingly, the thickness of the soak layer 250 may be related to the combined thickness of the conductive work function layers 248N and 248P. For example, for transistors having a relatively smaller combined thickness of the conductive work function layers 248N and 248P, the duration of the silicon precursor, and therefore, the thickness of the coating layer is relatively increased, and for transistors having a relatively greater combined thickness of the conductive work function layers 248N and 248P, the duration of the silicon precursor, and therefore, the thickness of the coating layer soak layer 250 is relatively decreased.

For example, in some embodiments, in a first transistor, the combined thickness of either of conductive work function layers 248N and 248P is about 5 A and the thickness of the soak layer 250 is about 10 A, and in a second transistor, the combined thickness of either of conductive work function layers 248N and 248P is about 10 A and the thickness of the soak layer 250 is about 5 A. In some embodiments, in a first transistor, the combined thickness of conductive work function layers 248N or 248P is about 5 A and the duration of providing the silicon precursor is about 500 s, and in a second transistor, the combined thickness of conductive work function layers 248N or 248P is about 10 A and the duration of providing the silicon precursor is about 200 s.

In certain embodiments, one or more, or all of steps of operations 18 and 20 are performed within the same integrated process system without exposing the structure to the ambient environment or to air. In some embodiments, steps of operation 18 and 20 may be performed in the same processing chamber, or in-situ with one process recipe to perform the operation 18 to deposit the conductive work function layers 248N and 248P and another process recipe to perform the operation 20 to deposit the soak layer 250.

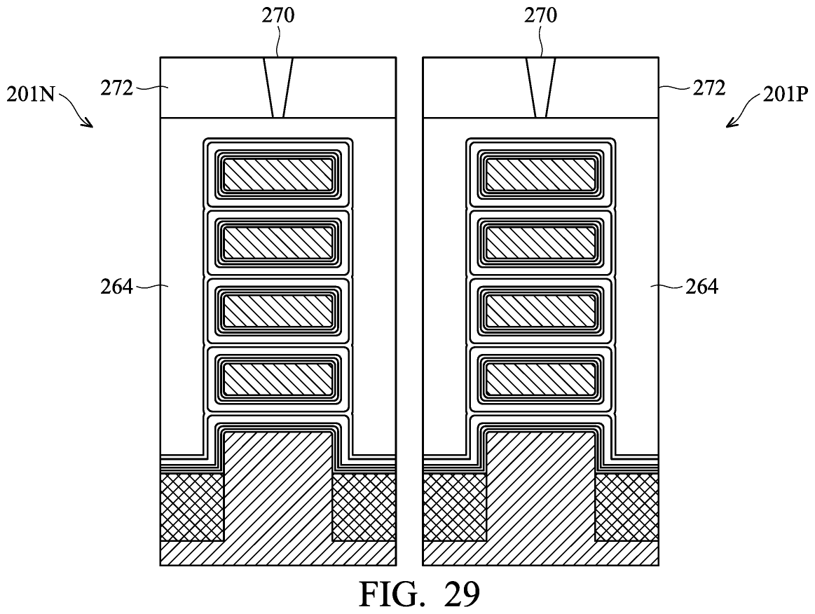

Referring to FIGS. 1 and 29, at operation 22 of the process 10 of FIG. 1, a fill metal layer 264 is deposited over the soak layer 250. In certain embodiments, the fill metal layer 264 may comprise Titanium, TiN, Tantalum, TaN, TaC, tungsten, cobalt, aluminum, ruthenium, copper, other suitable metals, multi-layers thereof, a combination thereof, multiple layers thereof, or the like. The fill metal layer 264 may be deposited by a suitable process, such as CVD, physical vapor deposition (PVD), sputtering, ALD, PECVD, plating, or other deposition processes.

In some embodiments, a glue metal layer (not shown) may be deposited, for example, by ALD, CVD, PVD, and/or other suitable process, on the soak layer 250, and the fill metal layer 264 is deposited on the glue layer. The glue layer may use materials that promote or enhance adhesion to the fill metal layer 264, which is to be formed on the glue layer. Exemplary glue layer materials include Ti, TiN, TaN, Ru, Mo, Al, WN, ZrSi2, MOSi2, TaSi2, NiSi2, WN, Ag, TaAl, TaAlC, TiAlN, TaC, TaCN, TaSiN, Mn, Zr, and/or combinations thereof.

Referring to FIGS. 1 and 29, at operation 24, method 10 performs further processing to complete the fabrication of the transistors. For example, at operation 24, method 10 may also form various contacts/vias 270, metal lines, as well as other multilayer interconnect features such as ILD layers 272 and interconnect layers, configured to connect the various features to form a functional circuit that may include the semiconductor devices.

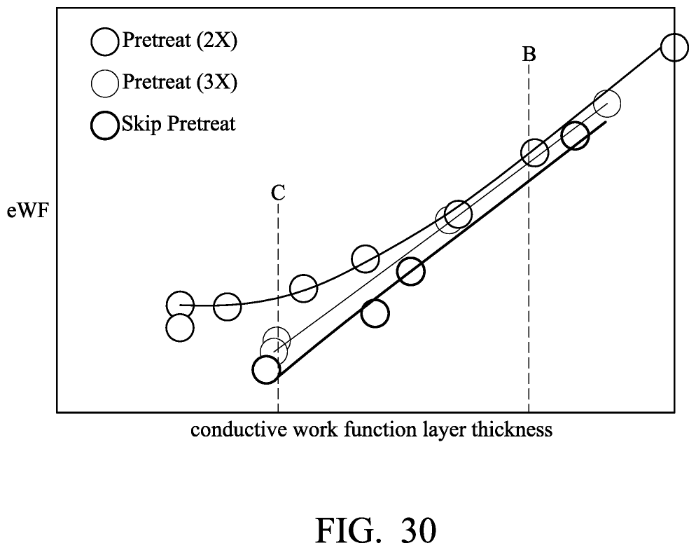

FIG. 30 is a graph illustrating improvement in transistor gate effective work function as a result of using one or more pretreatment layers. As shown, in the region near the line B, where the thickness of the conductive work function layers is relatively large, the transistor formed without pretreatment has a substantially linear relationship between effective work function and the conductive work function layers thickness, where the slope is relatively constant. However, in the region near the line C, where the thickness of the conductive work function layers is relatively small, the transistor formed without pretreatment the relationship between effective work function and the conductive work function layers thickness has dramatically changed such that thinner conductive work function layers thickness results in little or no change in effective work function. Sometimes, a transistor formed without pretreatment has a relationship between effective work function and the conductive work function layers thickness such that thinner conductive work function layers thickness results in greater effective work function.

As illustrated, transistors formed with 2 or 3 pretreatment cycles has a substantially linear relationship between effective work function and the combined conductive work function layers thickness such that lower effective work function is achievable with less combined thickness of the conductive work function layers.

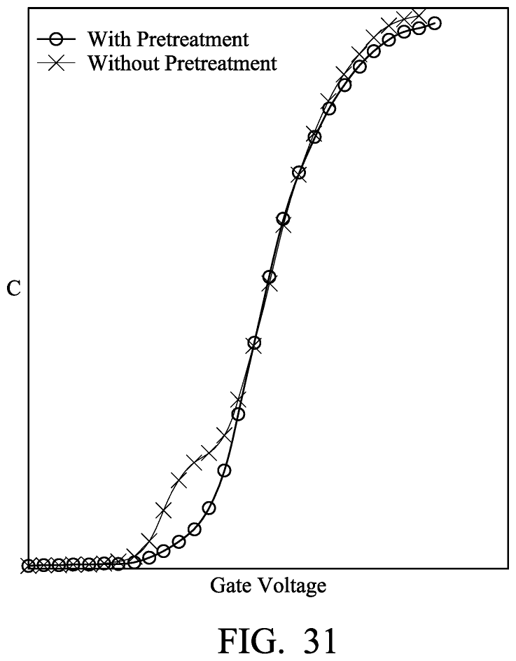

FIG. 31 is a graph showing Capacitance (C) vs. Gate Voltage for transistors formed with and without pretreatment. The graph illustrates improvement in transistor gate Dit as a result of using one or more pretreatment layers. As shown, for both transistors, as gate voltage is increased to cause a conductive channel to form, the capacitance increases, as expected. However, the transistor formed without pretreatment indicates unacceptable Dit, while the transistor formed with pretreatment indicates good Dit performance. In some embodiments, the Dit for transistors formed with pretreatment may be less than 1×10¹⁰/cm² eV.

As discussed in further detail above, transistors formed with one or more pretreatment layers allow for thin gate stacks, with controllable low effective work functions, and good Dit performance. Accordingly, transistors formed with one or more pretreatment layers are easily manufactured with tunable threshold voltages and good Dit performance.

One inventive aspect is a method of forming a semiconductor device. The method includes forming a first transistor including a first gate stack in a first region of a semiconductor substrate by at least: forming a first high-k dielectric constant layer on the semiconductor substrate, forming a first pretreatment layer (PL) on the first high-k dielectric constant layer, and forming a first conductive work function layer (WFL) on the first pretreatment layer, where the first conductive work function layer has a first WFL thickness. Forming the first transistor also includes forming a first coating layer on the first conductive work function layer, where the first gate stack has a first effective work function. The method also includes forming a second transistor including a second gate stack in a second region of the semiconductor substrate by at least: forming a second high-k dielectric constant layer on the semiconductor substrate, forming a second pretreatment layer on the second high-k dielectric constant layer, and forming a second conductive work function layer on the second pretreatment layer, where the second conductive work function layer has a second WFL thickness. Forming the second transistor also includes forming a second coating layer on the second conductive work function layer, where the second gate stack has a second effective work function. The first WFL thickness is greater than the second WFL thickness, and the first effective work function is greater than the second effective work function.

In some embodiments, at least one of the first and second transistors has a FinFET or a nanostructure transistor structure.

In some embodiments, the first and second pretreatment layers each include Aluminum.

In some embodiments, the first and second pretreatment layers each include Carbon.

In some embodiments, forming the first pretreatment layer on the first high-k dielectric constant layer and forming the second pretreatment layer on the second high-k dielectric constant layer each include performing 2 or 3 atomic layer deposition (ALD) cycles, where at least one atomic layer deposition (ALD) cycle is performed with one or more precursors selected from a group containing Triethlyaluminum (TEA), Trimethlyaluminium (TMA), AlCl3, Titanium Chloride (TiClx), and Tantalum Chloride (TaClx).

In some embodiments, the first pretreatment layer has a first PL thickness, where the second pretreatment layer has a second PL thickness, and the first PL thickness is about equal to the second PL thickness.

In some embodiments, the first pretreatment layer has a first PL thickness, the second pretreatment layer has a second PL thickness, a ratio of the first WFL thickness to the first PL thickness is between about 0.7 and about 1.3, and a ratio of the second WFL thickness to the second PL thickness is between about 0.3 and about 0.7.

In some embodiments, a ratio of the first WFL thickness to the second WFL thickness is between about 1.5 and about 2.5.

Another inventive aspect is a method of forming a semiconductor device. The method includes forming a transistor including a gate stack on a semiconductor substrate by at least: forming a high-k dielectric constant layer on the semiconductor substrate, forming a pretreatment layer (PL) on the high-k dielectric constant layer, determining a thickness for a conductive work function layer (WFL) based on a target effective work function of the transistor, and forming the conductive work function layer (WFL) on the pretreatment layer, where the conductive work function layer has a WFL thickness substantially equal to the determined thickness. Forming the transistor also includes forming a coating layer on the conductive work function layer. The gate stack has a tuned effective work function according to the determined thickness.

In some embodiments, the pretreatment layer includes Aluminum.

In some embodiments, the pretreatment layer includes Carbon.

In some embodiments, forming the pretreatment layer on the high-k dielectric constant layer includes performing 2 or 3 atomic layer deposition (ALD) cycles, where at least one atomic layer deposition (ALD) cycle is performed with one or more precursors selected from a group containing Triethlyaluminum (TEA), Trimethlyaluminium (TMA), AlCl3, Titanium Chloride (TiClx), and Tantalum Chloride (TaClx).

In some embodiments, the transistor has a FinFET or a nanostructure transistor structure.

14. Another inventive aspect is a semiconductor device having a first transistor including a first gate stack in a first region of a semiconductor substrate, the first gate stack including a first high-k dielectric constant layer. The first transistor also includes a first preliminary layer (PL) on the first high-k dielectric constant layer, and a first conductive work function layer (WFL) on the first preliminary layer, where the first conductive work function layer has a first WFL thickness. The first transistor also includes a first coating layer on the first conductive work function layer, where the first gate stack has a first effective work function. The semiconductor device also has a second transistor including a second gate stack in a second region of the semiconductor substrate, the second gate stack including a second high-k dielectric constant layer. The second transistor also includes a second preliminary layer on the second high-k dielectric constant layer, and a second conductive work function layer on the second preliminary layer, where the second conductive work function layer has a second WFL thickness. The second transistor also includes a second coating layer on the second conductive work function layer, where the second gate stack has a second effective work function. The first WFL thickness is greater than the second WFL thickness, and the first effective work function is greater than the second effective work function at least partly because the first WFL thickness is greater than the second WFL thickness.

In some embodiments, at least one of the first and second transistors has a FinFET or a nanostructure transistor structure.

In some embodiments, the first and second preliminary layers each include Aluminum.

In some embodiments, the first and second preliminary layers each include Carbon.

In some embodiments, the first preliminary layer has a first PL thickness, where the second preliminary layer has a second PL thickness, and where the first PL thickness is about equal to the second PL thickness.

In some embodiments, the first preliminary layer has a first PL thickness, where the second preliminary layer has a second PL thickness, where a ratio of the first WFL thickness to the first PL thickness is between about 0.7 and about 1.3, and where a ratio of the second WFL thickness to the second PL thickness is between about 0.3 and about 0.7.

In some embodiments, a ratio of the first WFL thickness to the second WFL thickness is between about 1.5 and about 2.5.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a first transistor comprising a first gate stack in a first region of a semiconductor substrate by at least:
forming a first high-k dielectric constant layer on the semiconductor substrate,
forming a first pretreatment layer (PL) on the first high-k dielectric constant layer,
forming a first conductive work function layer (WFL) on the first pretreatment layer, wherein the first conductive work function layer has a first WFL thickness, and
forming a first coating layer on the first conductive work function layer,
wherein the first gate stack has a first effective work function; and
forming a second transistor comprising a second gate stack in a second region of the semiconductor substrate by at least:
forming a second high-k dielectric constant layer on the semiconductor substrate,
forming a second pretreatment layer on the second high-k dielectric constant layer,
forming a second conductive work function layer on the second pretreatment layer, wherein the second conductive work function layer has a second WFL thickness, and
forming a second coating layer on the second conductive work function layer,
wherein the second gate stack has a second effective work function,
wherein the first WFL thickness is greater than the second WFL thickness, and wherein the first effective work function is greater than the second effective work function.

2. The method of claim 1, wherein at least one of the first and second transistors has a FinFET or a nanostructure transistor structure.

3. The method of claim 1, wherein the first and second pretreatment layers each comprise Aluminum.

4. The method of claim 3, wherein the first and second pretreatment layers each comprise Carbon.

5. The method of claim 1, wherein forming the first pretreatment layer on the first high-k dielectric constant layer and forming the second pretreatment layer on the second high-k dielectric constant layer each comprise performing 2 or 3 atomic layer deposition (ALD) cycles, wherein at least one atomic layer deposition (ALD) cycle is performed with one or more precursors selected from a group containing Triethlyaluminum (TEA), Trimethlyaluminium (TMA), AlCl₃, Titanium Chloride (TiClx), and Tantalum Chloride (TaClx).

6. The method of claim 1, wherein the first pretreatment layer has a first PL thickness, wherein the second pretreatment layer has a second PL thickness, and wherein the first PL thickness is about equal to the second PL thickness.

7. The method of claim 1, wherein the first pretreatment layer has a first PL thickness, wherein the second pretreatment layer has a second PL thickness, wherein a ratio of the first WFL thickness to the first PL thickness is between about 0.7 and about 1.3, and wherein a ratio of the second WFL thickness to the second PL thickness is between about 0.3 and about 0.7.

8. The method of claim 1, wherein a ratio of the first WFL thickness to the second WFL thickness is between about 1.5 and about 2.5.

9. A method of forming a semiconductor device, the method comprising:
forming a transistor comprising a gate stack on a semiconductor substrate by at least:
forming a high-k dielectric constant layer on the semiconductor substrate,
forming a pretreatment layer (PL) on the high-k dielectric constant layer,
determining a thickness for a conductive work function layer (WFL) based on a target effective work function of the transistor,
forming the WFL on the pretreatment layer, wherein the conductive work function layer has a WFL thickness substantially equal to the determined thickness, and
forming a coating layer on the conductive work function layer,
wherein the gate stack has a tuned effective work function according to the determined thickness.

10. The method of claim 9, wherein the pretreatment layer comprises Aluminum.

11. The method of claim 10, wherein the pretreatment layer comprises Carbon.

12. The method of claim 9, wherein forming the pretreatment layer on the high-k dielectric constant layer comprises performing 2 or 3 atomic layer deposition (ALD) cycles, wherein at least one atomic layer deposition (ALD) cycle is performed with one or more precursors selected from a group containing Triethlyaluminum (TEA), Trimethlyaluminium (TMA), AlCl₃, Titanium Chloride (TiClx), and Tantalum Chloride (TaClx).

13. The method of claim 9, wherein the transistor has a FinFET or a nanostructure transistor structure.

14. A semiconductor device, comprising:
a first transistor comprising a first gate stack in a first region of a semiconductor substrate, the first gate stack comprising:
a first high-k dielectric constant layer,
a first preliminary layer (PL) on the first high-k dielectric constant layer,
a first conductive work function layer (WFL) on the first preliminary layer, wherein the first conductive work function layer has a first WFL thickness, and
a first coating layer on the first conductive work function layer,
wherein the first gate stack has a first effective work function; and
a second transistor comprising a second gate stack in a second region of the semiconductor substrate, the second gate stack comprising:
a second high-k dielectric constant layer,
a second preliminary layer on the second high-k dielectric constant layer,
a second conductive work function layer on the second preliminary layer, wherein the second conductive work function layer has a second WFL thickness, and
a second coating layer on the second conductive work function layer,
wherein the second gate stack has a second effective work function,
wherein the first WFL thickness is greater than the second WFL thickness, and wherein the first effective work function is greater than the second effective work function at least partly because the first WFL thickness is greater than the second WFL thickness.

15. The semiconductor device of claim 14, wherein at least one of the first and second transistors has a FinFET or a nanostructure transistor structure.

16. The semiconductor device of claim 14, wherein the first and second preliminary layers each comprise Aluminum.

17. The semiconductor device of claim 16, wherein the first and second preliminary layers each comprise Carbon.

18. The semiconductor device of claim 14, wherein the first preliminary layer has a first PL thickness, wherein the second preliminary layer has a second PL thickness, and wherein the first PL thickness is about equal to the second PL thickness.

19. The semiconductor device of claim 14, wherein the first preliminary layer has a first PL thickness, wherein the second preliminary layer has a second PL thickness, wherein a ratio of the first WFL thickness to the first PL thickness is between about 0.7 and about 1.3, and wherein a ratio of the second WFL thickness to the second PL thickness is between about 0.3 and about 0.7.

20. The semiconductor device of claim 14, wherein a ratio of the first WFL thickness to the second WFL thickness is between about 1.5 and about 2.5.
